(19) United States
(12) Patent Application Publication
(10) Pub. No.: US 2026/0122968 A1
(43) Pub. Date: Apr. 30, 2026

(54) SEMICONDUCTOR DEVICE AND METHODS OF FORMING THE SAME

(71) Applicant: TAIWAN SEMICONDUCTOR MANUFACTURING COMPANY, LTD., Hsinchu (TW)

(72) Inventors: Yu-Chun LAI, Taichung (TW); Ching-Feng FU, Taichung (TW); Fu-Sheng LI, Taichung (TW); Hsin-Yeh CHANG, Hsinchu (TW)

(21) Appl. No.: 18/928,309

(22) Filed: Oct. 28, 2024

(51) Int. Cl. H01L 29/423; H01L 21/762; H01L 21/8234; H01L 27/088; H01L 29/06; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 64/017; H10D 84/0149; H10D 84/038; H10D 84/83; H10W 10/014; H10W 10/17

(57) ABSTRACT

Embodiments of the present disclosure is a semiconductor device that, for example, includes: a channel region connecting to an epitaxial structure in a first direction; a gate structure disposed over the channel region and having a longitudinal axis extending in a second direction substantially perpendicular to the first direction; and a contact disposed over the epitaxial structure, the contact including a sidewall in the second direction, wherein a first angle between the sidewall and a top surface of the contact is greater than 90 degrees.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-6 are perspective views of various stages of manufacturing a semiconductor device, in accordance with some embodiments.

FIGS. 7A-24C are cross-sectional views and plan views of various stages of manufacturing a semiconductor device, in accordance with some embodiments.

FIGS. 25A-25D are cross-sectional views and a plan view of an intermediate stage of manufacturing a semiconductor device, in accordance with some embodiments.

FIGS. 26A-26C are cross-sectional views and a plan view of an intermediate stage of manufacturing a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provides methods for forming source/drain contacts and structures manufactured thereof. In some embodiments, the methods for forming the source/drain contacts may include forming metal lines and cutting the metal lines by an end-cut process to separate the metal lines to the source/drain contacts. The end-cut process may provide precise critical dimension control and thus can help mitigate the risks of forming shorts between adjacent source/drain contacts and/or between a gate structure and its adjacent source/drain contact.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

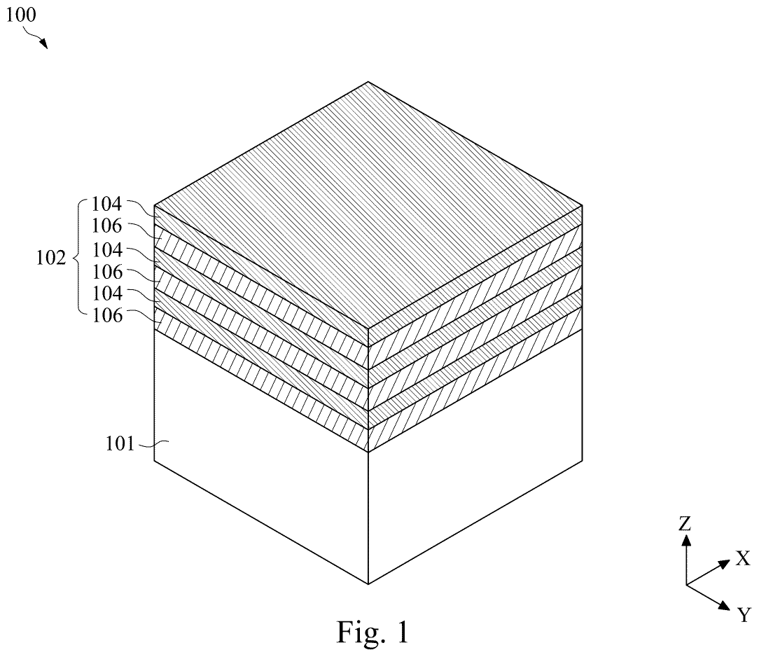

FIGS. 1-24C show exemplary processes for manufacturing a semiconductor device 100 according to embodiments of the present disclosure. It is understood that additional operations can be provided before, during, and after processes shown by FIGS. 1-24C, and some of the operations described below can be replaced or eliminated, for additional embodiments of the method. The order of the operations/processes is not limiting and may be interchangeable.

FIGS. 1-6 are perspective views of intermediate stages in manufacturing a semiconductor device 100, in accordance with some embodiments. The semiconductor device 100 also includes a multilayer stack 102 formed over the substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. The substrate 101 may include various regions that have been doped with impurities (e.g., dopants having p-type or n-type conductivity) in the substrate 101. Depending on circuit design, the substrate 101 may include p-type doped wells for an n-type field effect transistors (NFET) n-type doped wells for a p-type field effect transistors (PFET).

The multilayer stack 102 includes alternating semiconductor layers made of different materials to facilitate the formation of nanostructure channels in a multi-gate device, such as nanostructure channel FETs. In some embodiments, the multilayer stack 102 includes first semiconductor layers 104 and second semiconductor layers 106 that are alternately stacked over the substrate 101. For example, the multilayer stack 102 is illustrated as including three layers of first semiconductor layers 104 and three layers of second semiconductor layers 106 for illustrative purposes. It is appreciated that any number of the first and second semiconductor layers 104, 106 can be included in the multilayer stack 102. In some embodiments, the first semiconductor layers 104 are formed of a first semiconductor material, and the second semiconductor layers 106 are formed of a second semiconductor material different from the first semiconductor material. The second semiconductor material may have a different etch selectively and/or oxidation rate than the first semiconductor material. In some embodiments, either the first semiconductor material or the second semiconductor material is or includes a material such as SiGe, SiC, GeAs, GaP, InP, InAs, InSb, GaAsP, AlInAs, AlGaAs, InGaAs, GaInP, GaInAsP, combinations thereof, or the like. In some embodiments, the first semiconductor material is formed of Si, and the second semiconductor material is formed of SiGe, or vice versa.

Each first semiconductor layer 104 may have a thickness in a range between about 5 nm and about 30 nm. Each second semiconductor layer 106 may have a thickness that is equal, less, or greater than the thickness of the first semiconductor layer 104. In some embodiments, each second semiconductor layer 106 has a thickness in a range between about 2 nm and about 50 nm. The first and second semiconductor layers 104, 106 are formed by any suitable deposition process, such as epitaxy deposition. By way of example, the epitaxial deposition of the multilayer stack 102 may be performed by vapor-phase epitaxy (VPE), molecular beam epitaxy (MBE), chemical vapor deposition (CVD), low-pressure metalorganic chemical vapor deposition (MOCVD) process, atomic layer deposition (ALD), the like, and/or other suitable epitaxial growth processes.

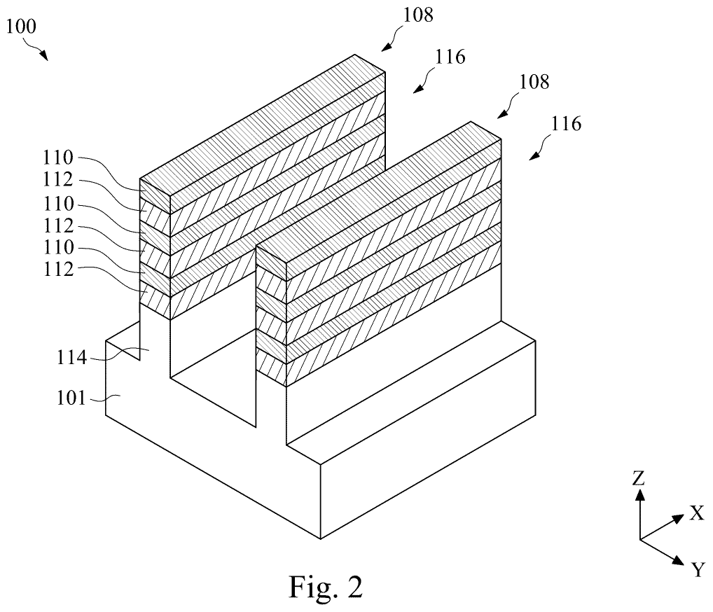

In FIG. 2, the multilayer stack 102 and the substrate 101 are patterned by one or more etch processes to form semiconductor strips 108, in accordance with some embodiments. Each semiconductor strip 108 may include first nanostructures 110 patterned from the first semiconductor layers 104 and second nanostructures 112 patterned from the second semiconductor layers 106. The substrate 101 may include a plurality of fins 114 after the etch processes. The semiconductor strips 108 are disposed over the fins 114, respectively. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section.

The semiconductor strips 108 may be formed by patterning a hard mask layer (not shown) formed on the multilayer stack 102 using multi-patterning operations that include lithography and etch processes. The etch process can include dry etching such as reactive ion etching (RIE) or neutral beam etching (NBE), wet etching, and/or other suitable processes. The lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etch process forms trenches 116 in unprotected regions through the hard mask layer, through the multilayer stack 102, and into the substrate 101, thereby leaving the semiconductor strips 108 and the fins 114. The trenches 116 extend along the X direction. In some embodiments, the semiconductor strips 108 and the fins 114 have a longitudinal axis along the X direction.

The semiconductor device 100 may include a plurality of transistor structures. The first nanostructures 110 or portions thereof may form nanostructure channel(s) of the transistor structures in later fabrication stages, while the second nanostructures 112 may act as sacrificial layers in later fabrication stages for allowing the nanostructure channel(s) to be surrounded by gate structures. The transistor structures having the nanostructure channel(s) may be referred to as nanostructure transistors, nanosheet transistors, nanowire transistors, gate-all-around (GAA) transistors, multi-bridge channel (MBC) transistors, or any transistors having gate electrodes surrounding channels.

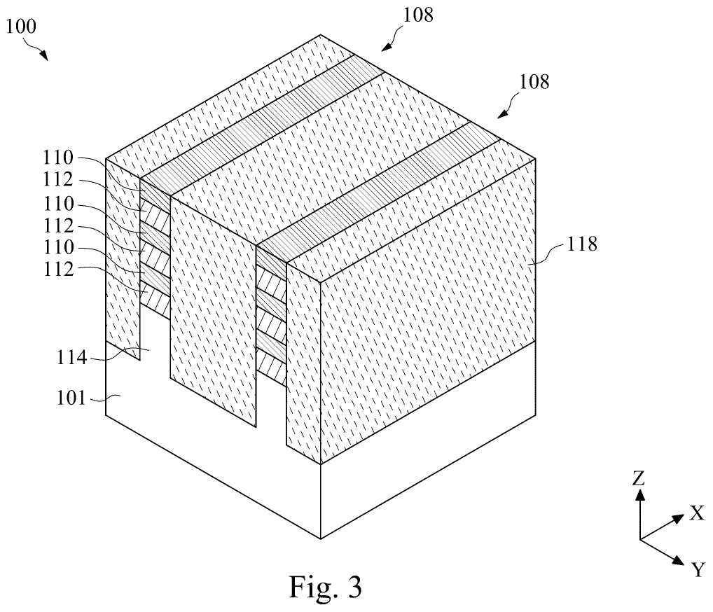

In FIG. 3, after the semiconductor strips 108 are formed, an insulating material 118 is formed over the substrate 101. The insulating material 118 fills the trenches 116 between neighboring semiconductor strips 108 until the semiconductor strips 108 are embedded in the insulating material 118. Then, a planarization operation, such as a chemical mechanical polishing (CMP) method and/or an etch-back method, is performed such that the top of the semiconductor strips 108 is exposed. The insulating material 118 may be made of silicon oxide, silicon nitride, silicon oxynitride (SiON), SiOCN, SiCN, fluorine-doped silicate glass (FSG), a low-K dielectric material (dielectric constant less than about 3.5), or any suitable dielectric material. The insulating material 118 may be formed by any suitable method, such as flowable CVD (FCVD), low-pressure chemical vapor deposition (LPCVD), or plasma-enhanced CVD (PECVD).

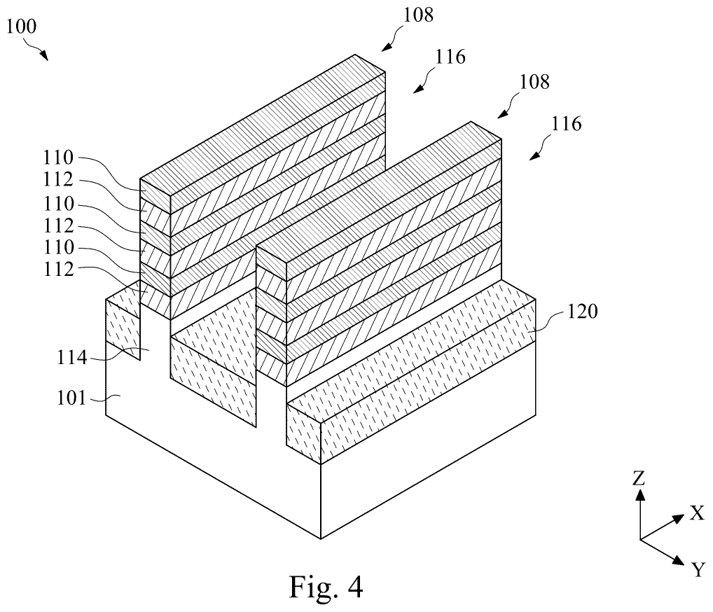

In FIG. 4, the insulating material 118 is recessed to form shallow trench isolation (STI) regions 120. The recess of the insulating material 118 exposes portions of the semiconductor strips 108 and the substrate 101. The recess of the insulating material 118 reveals the trenches 116 between the neighboring semiconductor strips 108. The STI regions 120 may be formed using a suitable process, such as a dry etch process, a wet etch process, or a combination thereof. Top surfaces of the STI regions 120 may be level with or below top surfaces of the fins 114 and in contact with the fins 114.

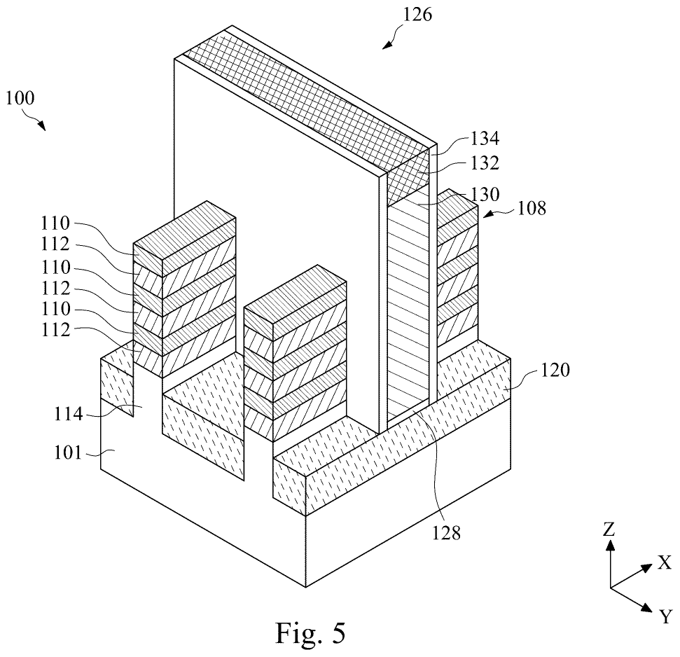

In FIG. 5, one or more dummy gate structures 126 (only one is shown) are formed over the semiconductor device 100. The dummy gate structures 126 are formed over a portion of the semiconductor strips 108. Each dummy gate structure 126 may include a dummy gate dielectric 128, a dummy gate electrode 130, and a hard mask 132. The dummy gate dielectric 128, the dummy gate electrode 130, and the hard mask 132 may be formed by sequentially depositing blanket layers of the dummy gate dielectric 128, the dummy gate electrode 130, and the hard mask 132, and then patterning those layers into the dummy gate structures 126. The dummy gate structure 126 may have a longitudinal direction (e.g., the Y-direction in FIG. 5) substantially perpendicular to the longitudinal directions of the semiconductor strips 108 (e.g., the X-direction in FIG. 5). The dummy gate structure 126 may land on the STI regions 120 and cross over a single one or a plurality of the semiconductor strips 108.

The dummy gate dielectric 128 may include one or more layers of dielectric material, such as a deposited oxide-based material (e.g., silicon oxide) or a material oxidized from the substrate 101. The dummy gate electrode 130 may include silicon such as polycrystalline silicon or amorphous silicon. The hard mask 132 may include one or more dielectric layers. For example, the hard mask 132 may be a combination of an oxide layer and a nitride layer.

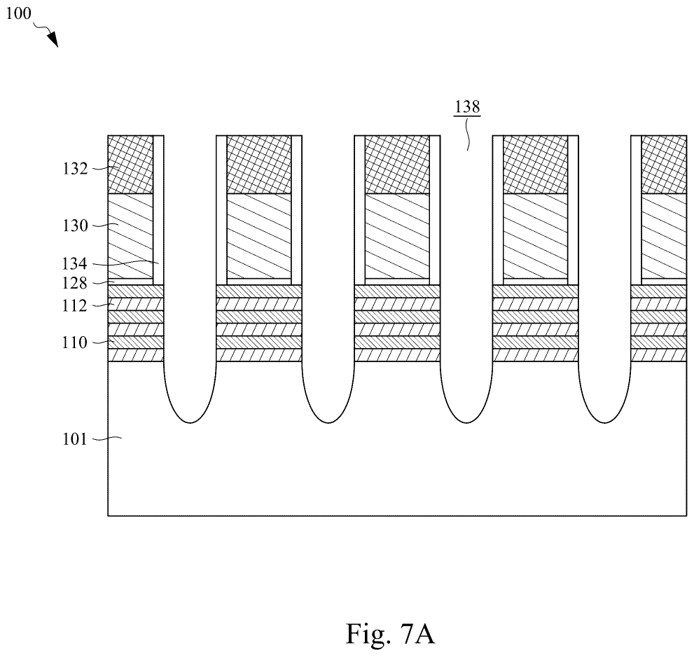

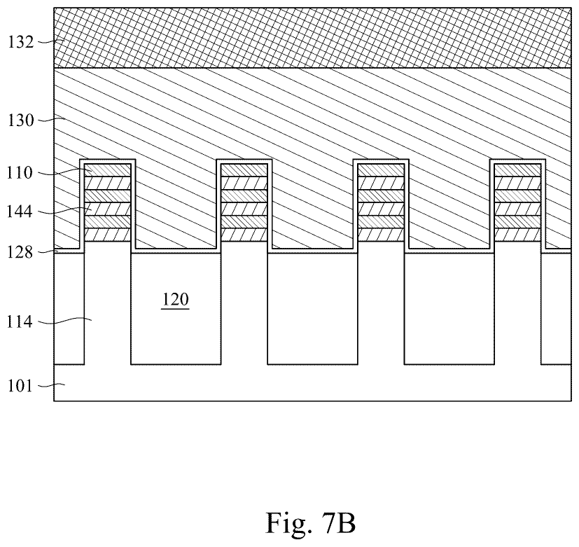

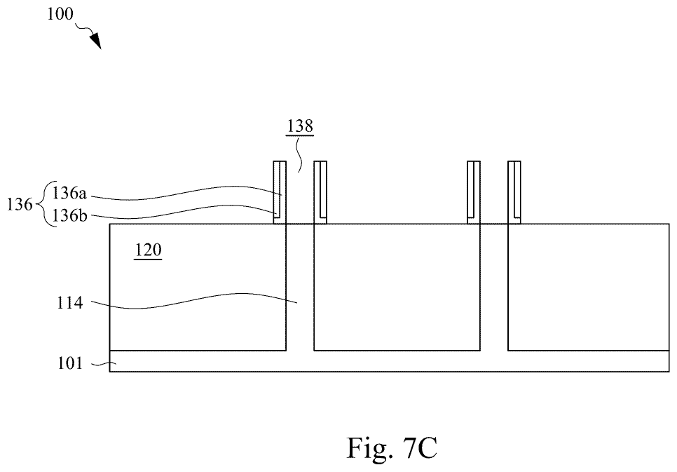

Gate spacers 134 are then formed on sidewalls of the dummy gate structure 126. The gate spacers 134 may be formed by conformally depositing one or more layers for the gate spacers 134 and anisotropically etching (e.g., RIE) the one or more layers. Dielectric materials such as silicon nitride (SiN), silicon oxide (SiO), silicon carbide (SiC), silicon oxide (SiOₓ), silicon carbo-nitride (SiCN), silicon oxynitride (SiON), silicon oxy-carbo-nitride (SiOCN), combinations thereof, or the like, may be used for the gate spacers 134. In some embodiments, spacer layers 136a and 136b (FIG. 7C) are also formed on sidewalls of the fins 114 in the same processes of forming the gate spacers 134.

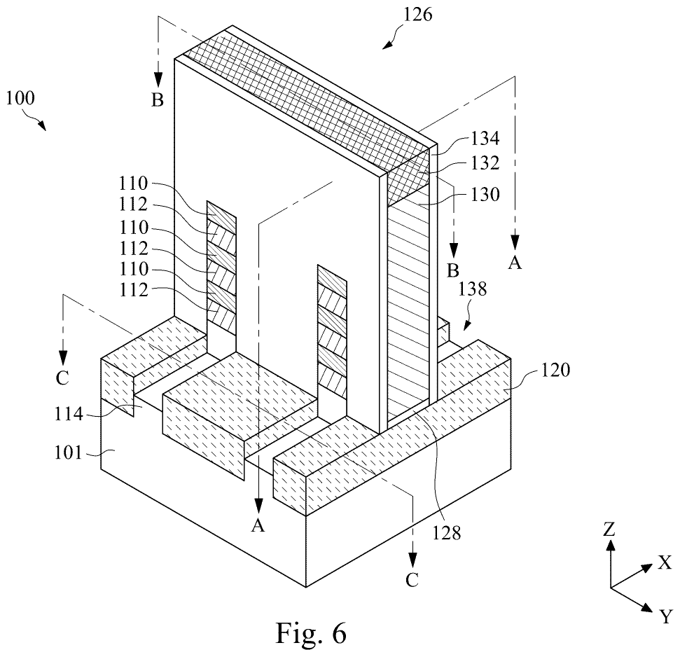

In FIG. 6, first openings 138 are formed in the semiconductor strips 108, the fins 114, and the substrate 101, in accordance with some embodiments. The first openings 138 may be formed by removing at least portions of the semiconductor strips 108 and the substrate 101 that are not protected by the gate spacers 134 and the dummy gate structures 126. As such, the first openings 138 may be formed between neighboring dummy gate structures 126 in the X-direction as illustrated in FIG. 6 (or the cross-sectional view illustrated in FIG. 7A). The first openings 138 may be recessed to below the top surfaces of the STI regions 120, although the first openings also can be recessed to level with or above the top surfaces of the STI regions 120. The first openings 138 may be formed by an etch process, either isotropic or anisotropic etch process, and the etch process may be selective with respect to one or more crystalline planes of the substrate 101. The etch process may be a dry etch, such as a RIE, NBE, or the like, or a wet etch. The etchant from the etch process may include fluorocarbons or chlorocarbons, such as CH₂Cl₂, C₂H₂F₂, C₂F₆, CF₄, or the like.

FIGS. 7A, 7B, and 7C are cross-sectional views of the semiconductor device 100 taken in directions along cross-section A-A, cross-section B-B of FIG. 6, and cross-section C-C of FIG. 6, respectively. Throughout the description, the figures with figure numbers including “A” are obtained from the reference cross-section A-A in FIG. 6; and Figure numbers including “B” are obtained from the reference cross-section B-B in FIG. 6; and Figure numbers including “C” are obtained from the reference cross-section C-C in FIG. 6. A plurality of dummy gate structures 126, a plurality of semiconductor strips 108 and more details are illustrated in the cross-sectional views, in accordance with some embodiments.

In FIGS. 7A, 7B and 7C, the first openings 138 extend through the stack of the first nanostructures 110 and the second nanostructures 112, and into the substrate 101. As illustrated in FIG. 7C, the spacer layers 136 are formed on opposite sidewalls of the fin 114, in accordance with some embodiments. Each of the spacer layers 136 may include a first spacer layer 136a and a second spacer layer 136b. In some embodiments, the first spacer layer 136a has an L-shape, and the second spacer layer 136b has an I shape, or vice versa. The first opening 138 is interposed between the first spacer layer 136a and expose the fin 114/substrate 101. Although FIG. 7C illustrates the fin 114 is below the spacer layer 136, and the top of the fin 114 may be higher than a bottom of the spacer layer 136 such that the fin 114 may be in physical contact with spacer layer 136.

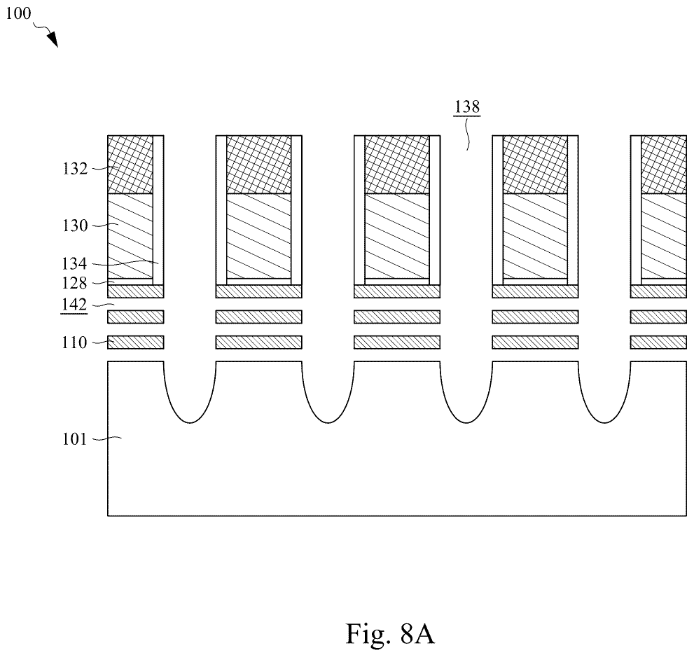

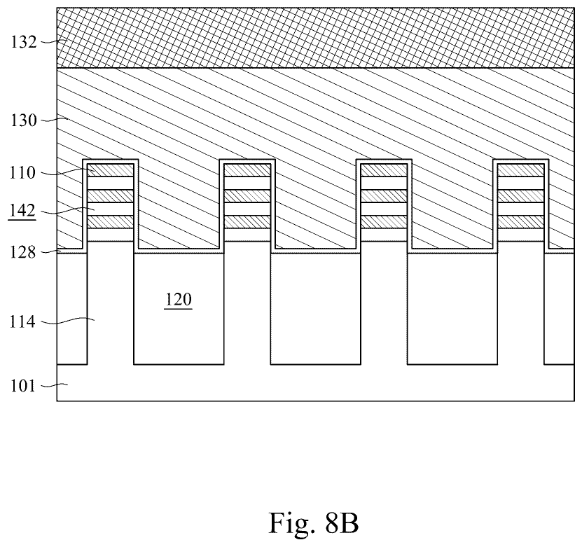

In FIGS. 8A and 8B, the second nanostructures 112 exposed by the first openings 138 are etched to form second openings 142, in accordance with some embodiments. That is, the second openings 142 may be space that was occupied by the second nanostructures 112, including the space between the vertically adjacent first nanostructures 110 and between the bottommost first nanostructure 110 and the substrate 101. While using etchants selective to etch the second semiconductor material of the second nanostructures 112, the first nanostructures 110 and the substrate 101 remain relatively unetched. In an embodiment that the second semiconductor material includes, e.g., SiGe, an etch process using a hydroxide etchant, such as tetramethylammonium hydroxide (TMAH), ammonium hydroxide (NH₄OH), or the like, is used.

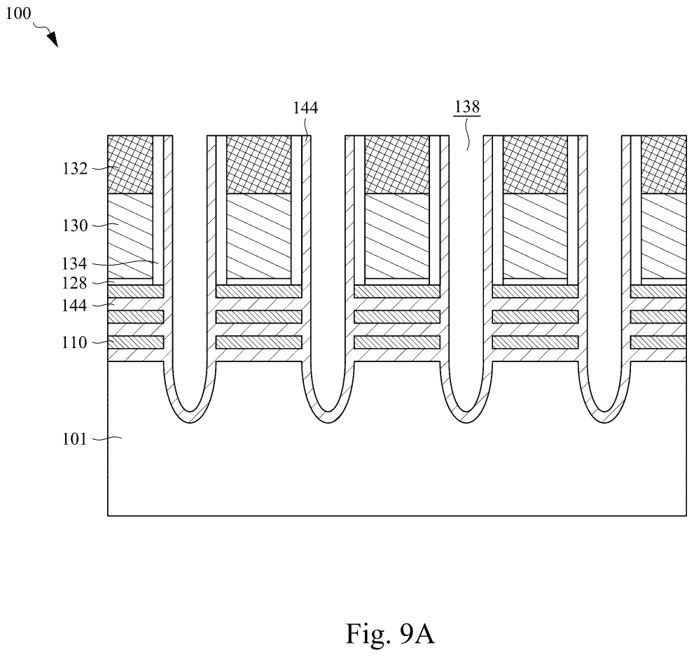

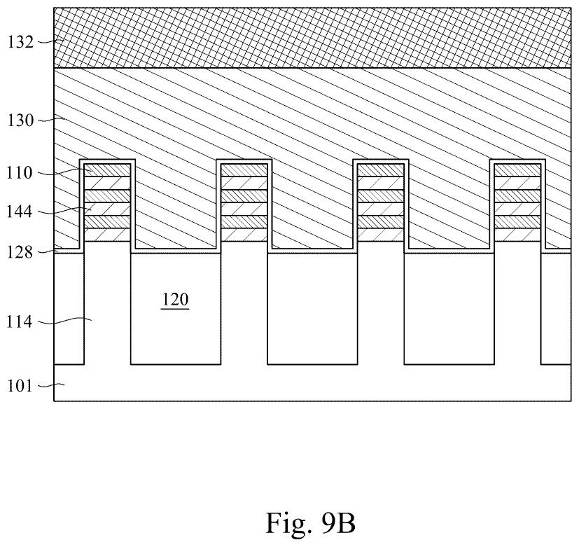

In FIGS. 9A and 9B, an insulating layer 144 is deposited in the first openings 138 and the second openings 142, in accordance with some embodiments. In some embodiments, given the size differences between the first openings 138 and the second openings 142, the insulating layer 144 may substantially or completely fill the second openings 142 and form a conformal layer in the first openings 138. The insulating layer 144 may include an oxide-containing material, such as silicon oxide, silicon oxynitride, fluorine-doped silicate glass (FSG), a low-K dielectric material, or any suitable dielectric material. In some embodiments, the insulating layer 144 includes a material similar to those of the STI regions 120. The insulating layer 144 may be formed by any suitable depositing method, such as FCVD, ALD, PECVD, LPCVD, combinations thereof, or the like.

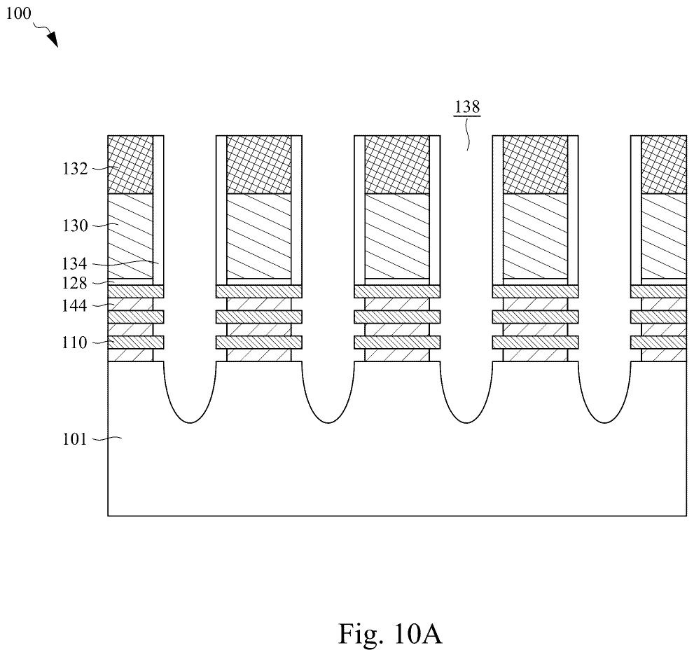

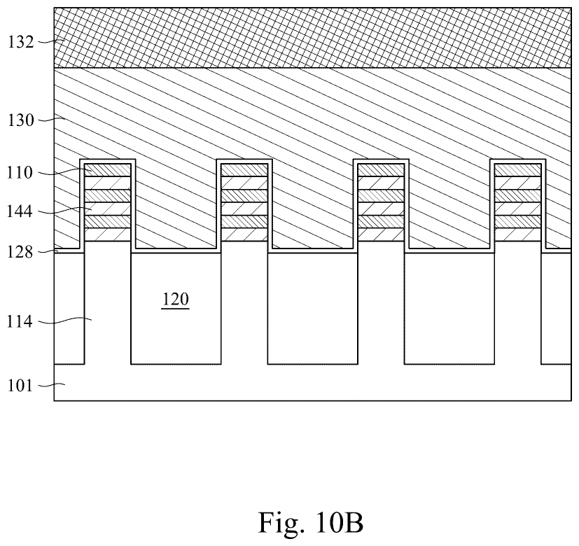

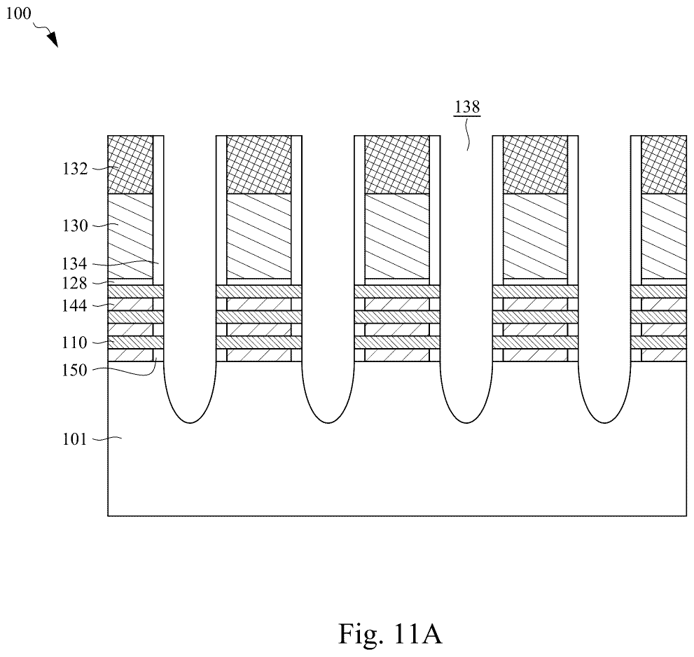

In FIGS. 10A and 10B, an etch process is performed to remove the insulating layer 144 in the first openings 138 and partially recess the insulating layer 144 in the second openings 142 (FIG. 8A), in accordance with some embodiments. The etch process may use etchants selective to etch the insulating layer 144, and the first nanostructures 110 and the substrate 101 may remain relatively unetched. The etch process may be an isotropic etch process. In some embodiments, the isotropic etch process is performed for a sufficient time to remove the insulating layer 144 in the first openings 138 and laterally recess the insulating layer 144 in the second openings 142. Accordingly, the insulating layer 144 is substantially or completely removed in the first openings 138. In an embodiment in which the insulating layer 144 remains in the first openings 138 after the isotropic etch process, a further anisotropic process may be performed to substantially or completely remove the insulating layer 144 in the first openings 138.

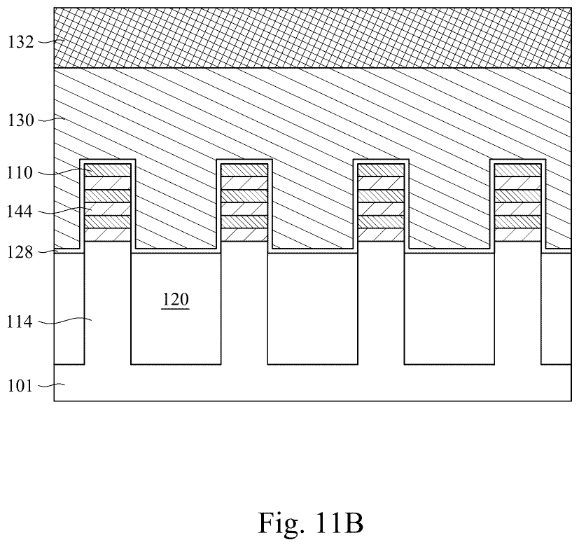

In FIGS. 11A and 11B, inner spacers 150 are formed in the lateral recesses and on the sidewalls of the insulating layer 144, in accordance with some embodiments. The inner spacers 150 may act as isolation features between subsequently formed epitaxial structures and a gate structure. As will be discussed in greater detail below, epitaxial structures will be formed in the first openings 138, and the insulating layer 144 will be replaced with gate structures.

In some embodiments, an inner spacer layer is deposited by a conformal deposition process, such as CVD, ALD, or the like. The inner spacer layer may include a material such as silicon nitride or silicon oxynitride, although any suitable material, such as a low-K dielectric material, may be utilized. The inner spacer layer may then be anisotropically etched to form the inner spacers 150, such as by RIE, NBE, or the like, using the gate spacers 134 as a mask. Although outer sidewalls of the inner spacers 150 are illustrated as being flush with sidewalls of the first nanostructures 110 in FIG. 11A, the outer sidewalls of the inner spacers 150 may extend beyond or be recessed from sidewalls of the first nanostructures 110. Moreover, although the outer sidewalls of the inner spacers 150 are illustrated as being straight in FIG. 11A, the outer sidewalls of the inner spacers 150 may be concave or convex.

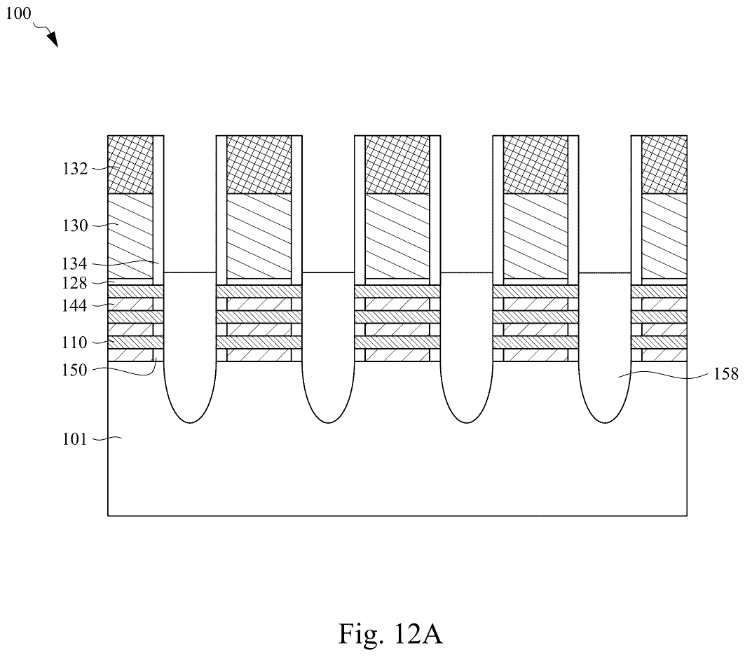

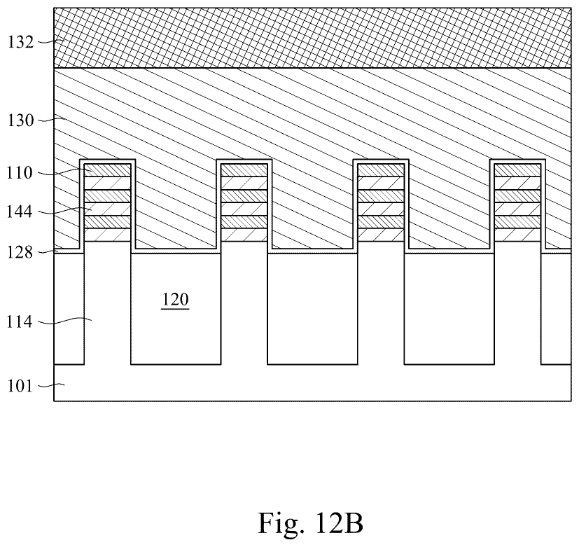

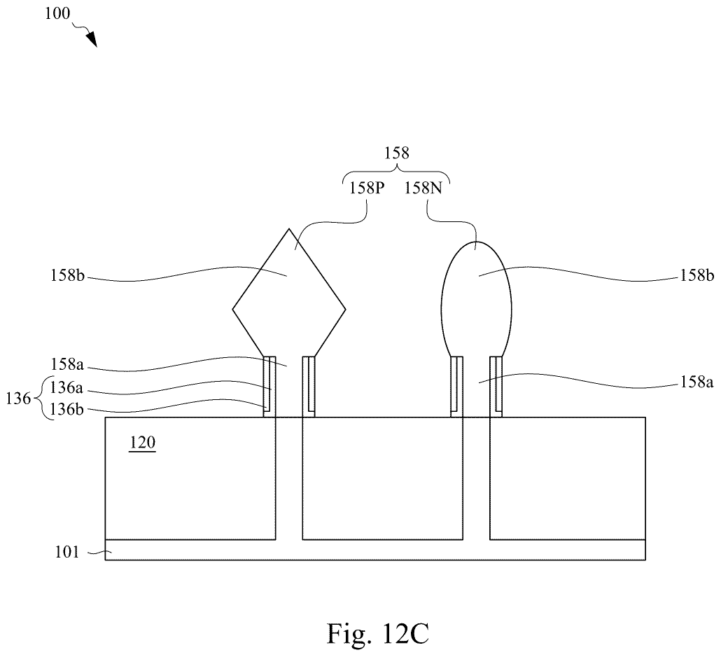

In FIGS. 12A-12C, epitaxial structures 158 are formed in the first openings 138, in accordance with some embodiments. The epitaxial structures 158 may be source/drain regions of the semiconductor device 100 and can also be referred to as epitaxial source/drain regions 158. In this disclosure, a source region and a drain region are interchangeably used, and the structures thereof are substantially the same. Furthermore, source/drain region(s) may refer to a source or a drain, individually or collectively dependent upon the context. The epitaxial structures 158 may be formed by an epitaxial growth method using such as, CVD, ALD, MBE, combinations therefore, or the like. In some embodiments, the impurities may be in situ doped when epitaxially depositing the epitaxial structures 158. The epitaxial structures 158 may have an impurity concentration of between about 1×10¹⁹ atoms/cm³ and about 1×10²¹ atoms/cm³. The epitaxial structures 158 may exert stress on the first nanostructures 110, thereby improving device performance.

In some embodiments, the epitaxial structures 158 include more than one epitaxial semiconductor layers. For example, each of the epitaxial structures 158 may comprise a first semiconductor material layer, a second semiconductor material layer, and a third semiconductor material layer. Any number of semiconductor material layers may be used for the epitaxial structures 158. Each of the first semiconductor material layer, the second semiconductor material layer, and the third semiconductor material layer may be formed of same or different semiconductor materials and may be doped to different dopant concentrations. In some embodiments, the first semiconductor material layer may have a dopant concentration less than the second semiconductor material layer and greater than the third semiconductor material layer. In embodiments in which the epitaxial structures 158 comprise three semiconductor material layers, the first semiconductor material layer may be deposited, the second semiconductor material layer may be deposited over the first semiconductor material layer, and the third semiconductor material layer may be deposited over the second semiconductor material layer.

FIG. 12C illustrates an n-type epitaxial structure 158N for n-type FETs (e.g., NMOS) and a p-type epitaxial structure 158P for p-type FETs (e.g., PMOS). In some embodiments, the n-type epitaxial structure 158N for the n-type FETs include Si, SiP, SiC, SiCP, and SiAs, and the p-type epitaxial structure 158P for the p-type FETs include Si, SiGe, Ge. For p-type FETs, p-type impurities, such as boron, boron fluoride, indium, or the like, may be included in the p-type epitaxial structure 158P. For n-type FETs, n-type impurities, such as phosphorus, arsenic, antimony, or the like, may be included in the n-type epitaxial structure 158N. In some embodiments, the p-type epitaxial structures 158P grow to form facets, which may correspond to crystalline planes of the material used for the substrate 101. In some embodiments, each of the p-type epitaxial structure 158P and the n-type epitaxial structure 158N includes a fin portion 158a interposed by the spacer layers 136 and a main structure 158b laterally extending outside the spacer layers 136. In some embodiments, the main structure 158b of the p-type epitaxial structure 158P has a diamond shape or the like. The n-type epitaxial structure 158N may not have facets.

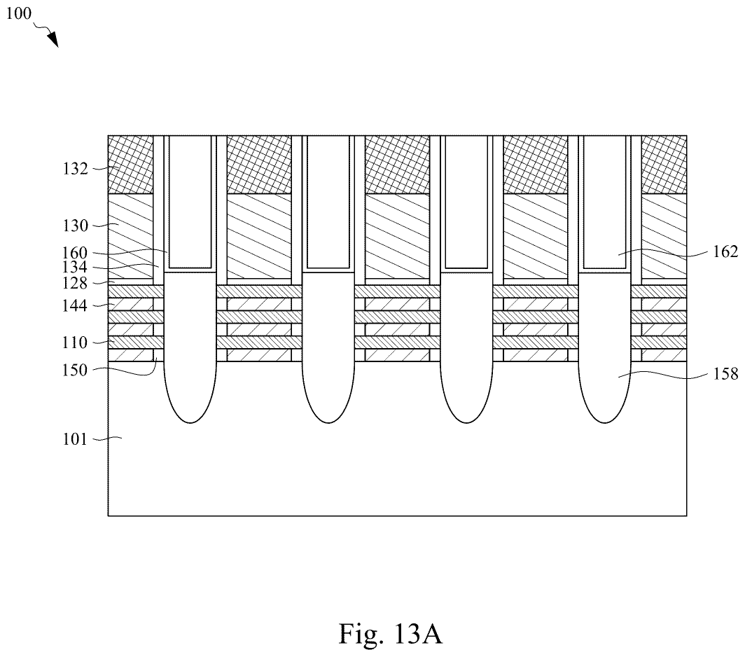

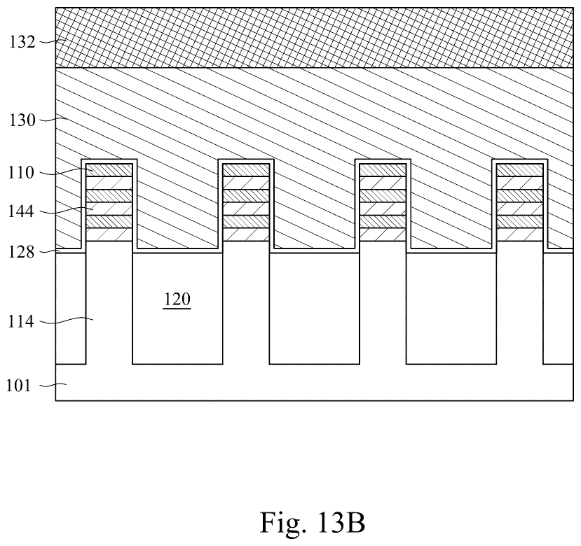

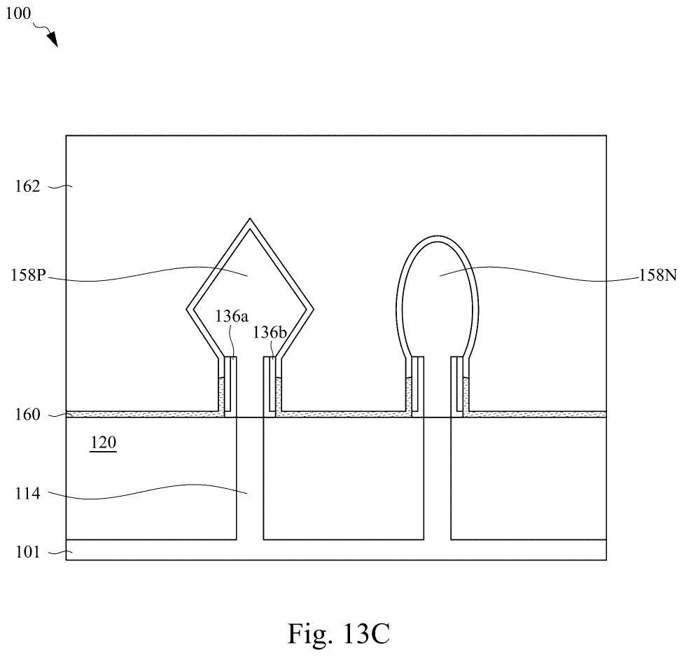

In FIGS. 13A, 13B, and 13C, a contact etch stop layer (CESL) 160 is conformally formed on the exposed surfaces of the semiconductor device 100, in accordance with some embodiments. The CESL 160 covers the STI regions 120, the source/drain regions 158, and the sidewalls of the gate spacers 134. The CESL 160 may include an oxygen-containing material or a nitrogen-containing material, such as silicon nitride, silicon carbon nitride, silicon oxynitride, silicon oxycarbide, combinations thereof, or the like. The CESL 160 may be formed by CVD, PECVD, ALD, or any suitable deposition technique. Next, a first interlayer dielectric (ILD) layer 162 is formed on the CESL 160 over the semiconductor device 100. The materials for the first ILD layer 162 may include compounds including Si, O, C, and/or H, such as silicon oxide, SiOCH, SiOC, PSG, BSG, BPSG, combinations thereof, or the like. Organic materials, such as polymers, may also be used for the first ILD layer 162. The first ILD layer 162 may be deposited by FCVD, PECVD, or other suitable deposition techniques. In some embodiments, after the first ILD layer 162 is deposited, a thermal process is performed to cure the first ILD layer 162. After the first ILD layer 162 is formed, a planarization operation, such as CMP, is performed to level the top surface of the first ILD layer 162 with the top surfaces of dummy gate electrodes 130 or the hard masks 132. In some embodiments in which the hard masks 132 remain, the planarization process levels the top surface of the first ILD layer 162 with the top surfaces of the hard masks 132 and the gate spacers 134. In some embodiments, top surfaces of the dummy gate electrodes 130, the gate spacers 134, and the first ILD layer 162 are level within process variations after the planarization process. In such embodiments, the top surfaces of the dummy gate electrodes 130 are exposed through the first ILD layer 162.

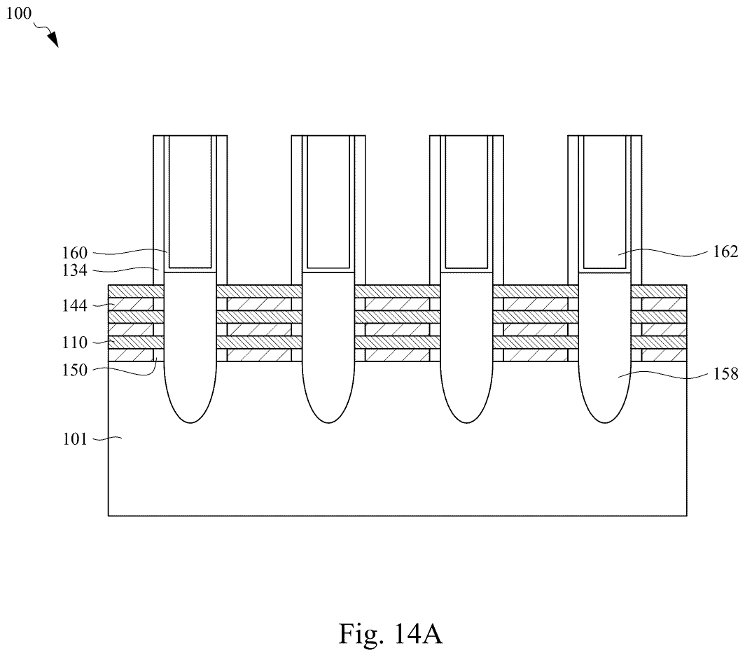

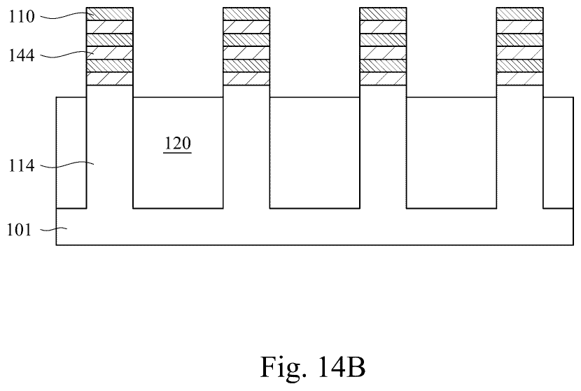

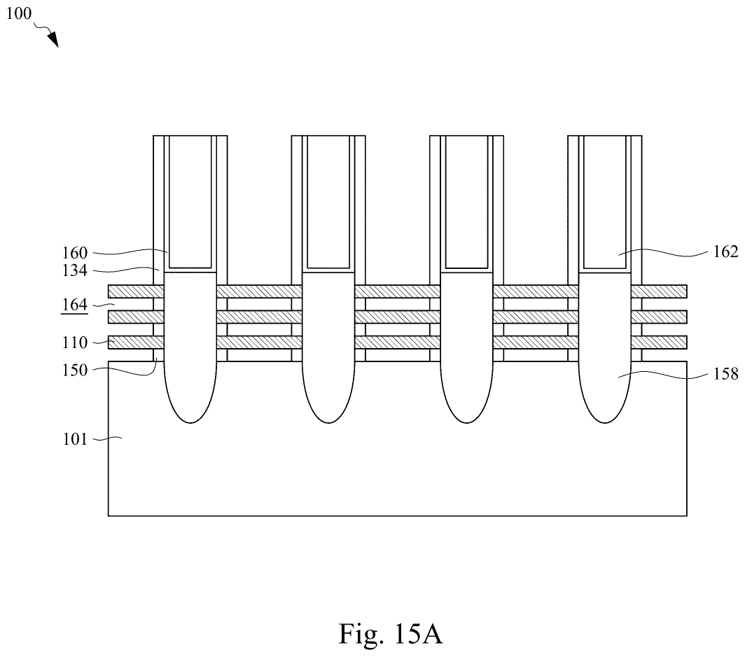

In FIGS. 14A and 14B, the dummy gate electrodes 130 and the hard masks 132 (if exist) are removed. In some embodiments, the dummy gate dielectrics 128 are also removed after the dummy gate electrodes 130 are removed. The hard masks 132, the dummy gate electrodes 130 and the dummy gate dielectrics 128 may be removed by one or more etch processes. For example, an etch process may be performed by etching the hard masks 132 using the dummy gate electrodes 130 as an etch stop, etching the dummy gate electrodes 130 using the dummy gate dielectrics 128 as an etch stop, and the dummy gate dielectrics 128 are then removed by another etch process. In some embodiments, the etch process for etching the dummy gate electrodes 130 and the dummy gate dielectrics 128 may include using reaction gas(es) that selectively etch the dummy gate electrodes 130 and the dummy gate dielectrics 128 at a faster rate than the first ILD layer 162 or the gate spacers 134. As illustrated in FIG. 14B, after the dummy gate dielectrics 128 and the dummy gate electrodes 130 are removed, the insulating layer 144 is exposed.

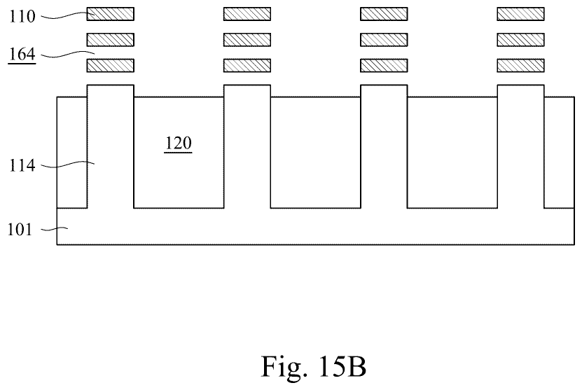

In FIGS. 15A and 15B, the insulating layer 144 is removed, in accordance with some embodiments. The insulating layer 144 may be removed by an isotropic etch process, such as by a wet etching containing an etchant containing a dilute HF or other suitable etchants. The removal of the hard masks 132, the dummy gate electrodes 130, the dummy gate dielectrics 128, and the insulating layer 144 forms third openings 164.

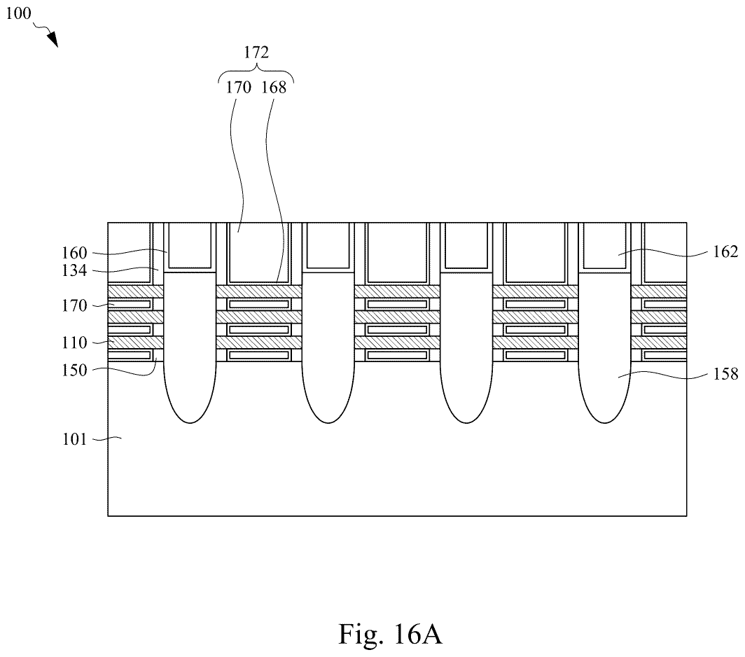

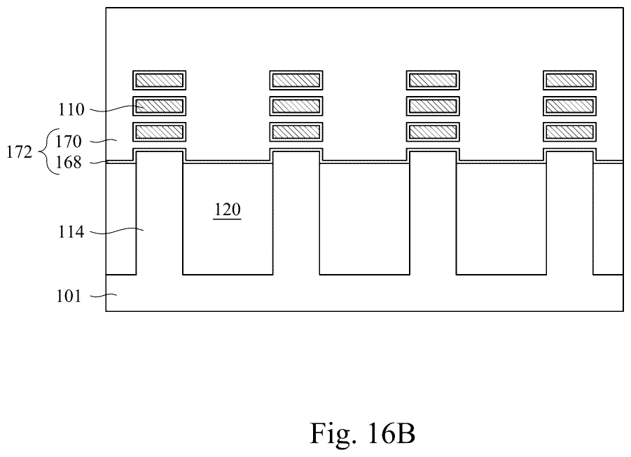

In FIGS. 16A and 16B, gate dielectric layers 168 and gate electrodes 170 are formed for replacement gates, in accordance with some embodiments. The gate dielectric layers 168 are deposited conformally in the third openings 164. The gate dielectric layers 168 may be formed on top surfaces and sidewalls of the substrate 101 and on exposed surfaces of the first nanostructures 110, In some embodiments, the gate dielectric layers 168 are also deposited on top surfaces of the first ILD layer 162, the CESL 160, the gate spacers 134, and the STI regions 120. In some embodiments, the gate dielectric layers 168 include one or more layers of a dielectric material, such as silicon oxide, silicon nitride, or high-K dielectric material, other suitable dielectric material, and/or combinations thereof. Examples of high-K dielectric material include HfO, HfSiO, HfSiON, HfTaO, HfTiO, HfZrO, ZrO, AlO, TiO, other suitable high-K dielectric materials, and/or combinations thereof. The gate dielectric layers 168 may be formed by CVD, ALD, or any suitable deposition techniques.

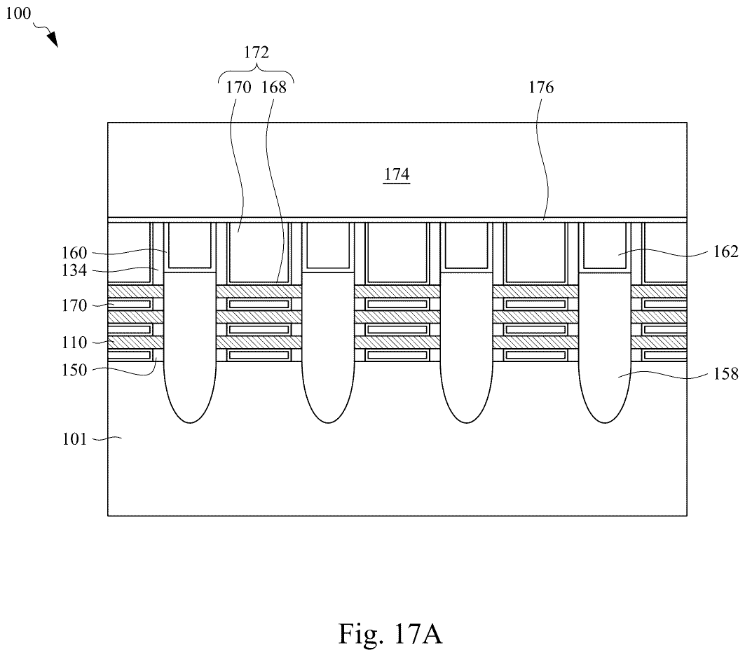

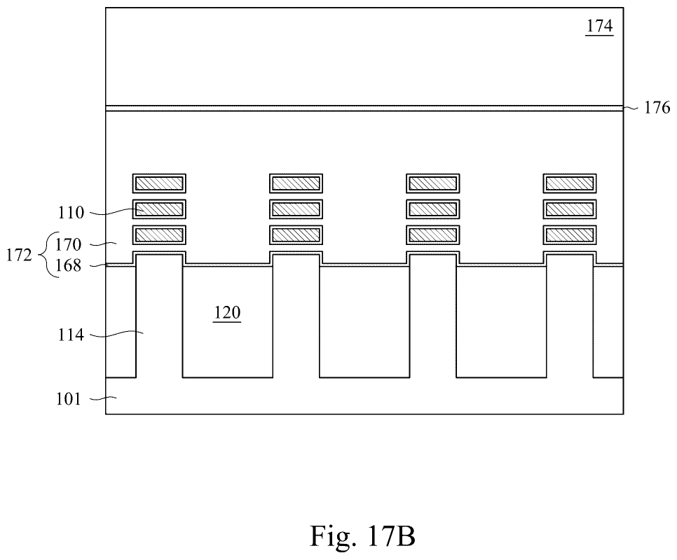

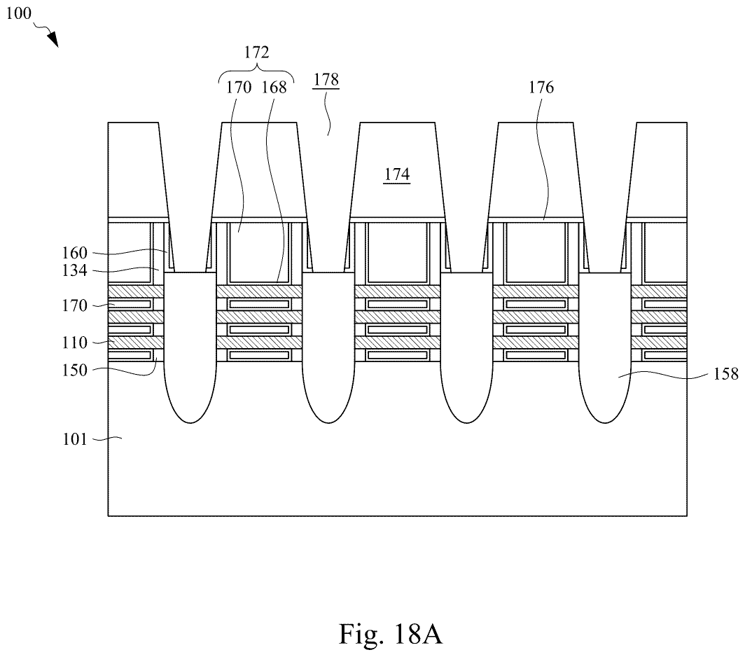

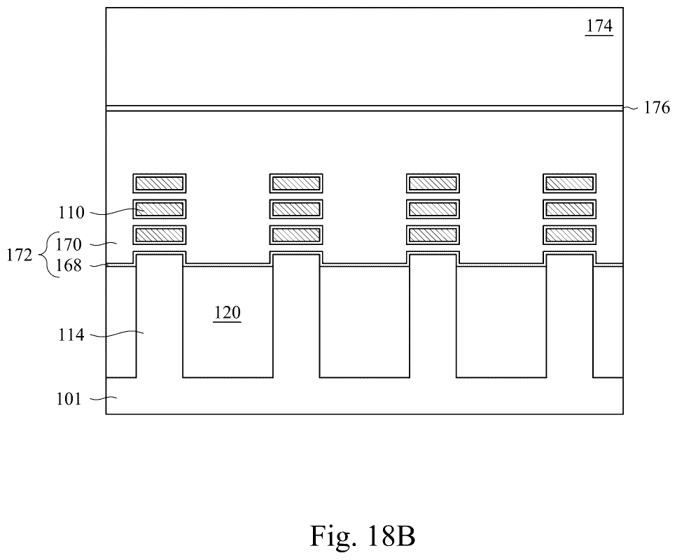

The gate electrodes 170 are deposited over the gate dielectric layer 168, respectively, and fill the remaining portions of the third openings 164. The gate electrodes 170 may include a metal-containing material such as titanium nitride, titanium oxide, tantalum nitride, tantalum carbide, cobalt, ruthenium, aluminum, tungsten, combinations thereof, or multi-layers thereof. Although single-layer gate electrodes 170 are illustrated in FIGS. 17A and 17B, the gate electrodes 170 may comprise any number of liner layers, any number of work function tuning layers, and a fill material. The gate electrodes 170 may be formed by CVD, ALD, electro-plating, or other suitable deposition techniques. After filling the third openings 164, excess materials of the gate dielectric layers 168 and the gate electrodes 170 over the top surface of the first ILD layer 162 are then removed by a planarization process, such as CMP, until the top surfaces of the first ILD layer 162 are exposed. The remaining portions of the gate electrodes 170 and the gate dielectric layers 168 thus form replacement gate structures of the semiconductor device 100. The gate electrodes 170 and the gate dielectric layers 168 may be collectively referred to as gate structures 172. The gate structures 172 may surround channels (i.e., the first nanostructures 110) of the semiconductor device 100.

As further illustrated by FIGS. 17A and 17B, a second ILD layer 174 is deposited over the first ILD layer 162. In some embodiments, the second ILD layer 174 is formed of a dielectric material similar to those of the first ILD layer 162 and is formed by methods similar to those used for the first ILD layer 162. In some embodiments, a CESL 176 is also formed before forming the second ILD layer 174. The CESL 176 may include a material similar to those of the CESL 160 and may be formed using methods similar to those used for the CESL 160. For example, the CESL 176 may include silicon nitride, silicon carbon nitride, silicon oxynitride, silicon oxycarbide, combinations thereof, or the like.

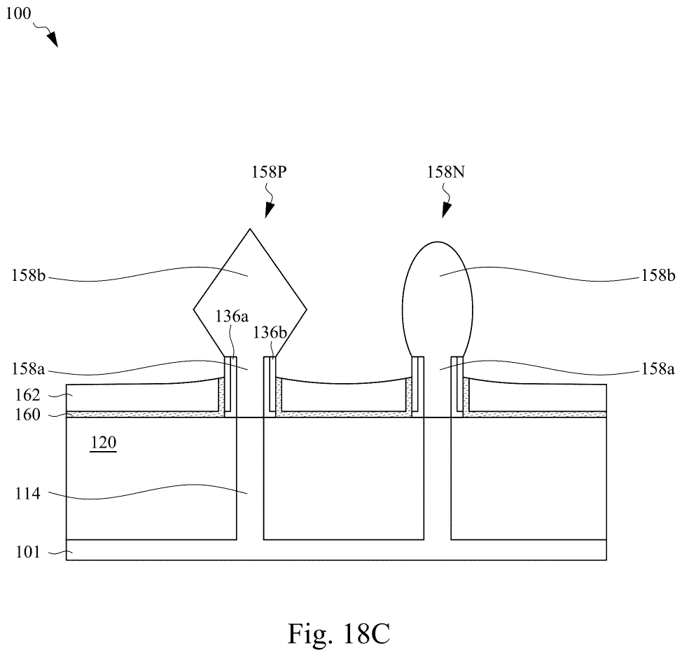

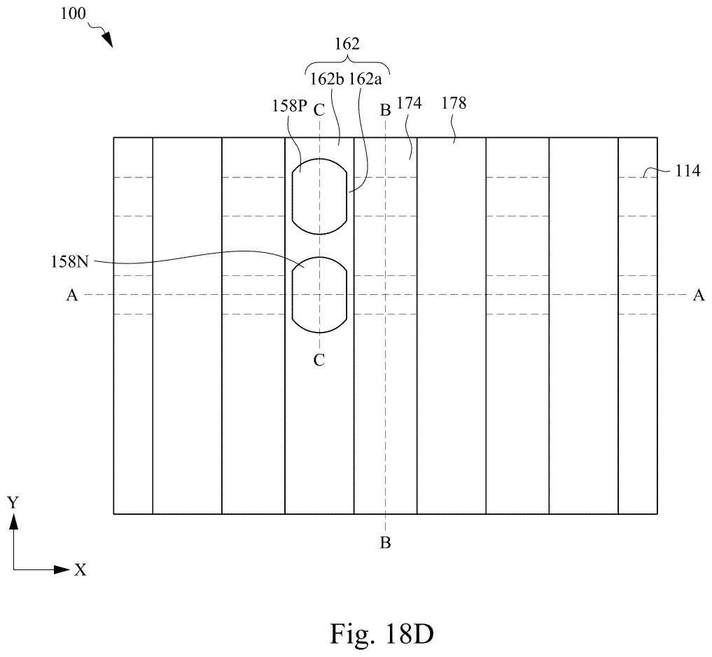

FIGS. 18A-18D illustrate that once the second ILD layer 174 and the CESL 176 are formed, an etch process is formed to form trenches 178, in accordance with some embodiments. In some embodiments, FIG. 18D is a plan view of the semiconductor device 100. Throughout the description, the figures with figure numbers including “D” are obtained from the plan view of the semiconductor device 100. FIG. 18A is a cross-sectional view of the A-A section in FIG. 18D, FIG. 18B is a cross-sectional view of the B-B section in FIG. 18D, and FIG. 18C is a cross-sectional view of the C-C section in FIG. 18D, in accordance with some embodiments. The A-A section may be along the X-direction as illustrated in FIG. 6 or FIG. 18D, and the B-B section and the C-C section may be along the Y-direction as illustrated in FIG. 6 or FIG. 18D. Referring to FIG. 18D, each of the trenches 178 may have a pattern of straight lines. For example, each of the trenches 178 may have a longitudinal axis extending along the longitudinal axis of the gate electrodes 170, such as along the Y-direction.

Referring to FIG. 18A, the etch process may include etching the second ILD layer 174, the CESL 176, the first ILD layer 162, and the CESL 160. As such, the trenches 178 may extend from a top surface of the second ILD layer 174 to expose the epitaxial structures 158. Each of the trenches 178 may have tapered sidewalls or vertical sidewalls extending from top surface of the second ILD layer 174 to the epitaxial structures 158 in the X-direction. In some embodiments that tapered sidewalls are implemented, a portion of the first ILD layer 162 and CESL 176 may remain between trenches 178 and the gate structures 172 in the X-direction.

Also referring to FIG. 18C, the trenches 178 may extend to below a top surface of the spacer layers 136 or below the main structure 158b of the epitaxial structures 158. As such, after forming the trenches 178, the first ILD layer 162 are separated into multiple portions. For example, as illustrated in FIG. 18D, the first ILD layer 162 may include first portions 162a that are disposed over the sidewalls of the gate spacers 134 and has a longitudinal axis extending in the Y-direction. The first portions of the first ILD layer 162 may include a portion disposed over the epitaxial structures 158. The first ILD layer 162 may also include second portions that are disposed over the STI regions 120 and recessed to have a height lower than the top surfaces of the spacer layers 136. Each of the ILD layer 162 may have a line shape extending in the Y-direction and have a length greater than the length of the epitaxial structure 158 in the Y-direction, such as having a length that is greater than at least about 3 times of the length of one respective epitaxial structure 158 in the Y-direction.

In some embodiments, the formation of the trenches 178 includes one or more etch processes. For example, one or more mask layers, such as one or more photoresist layers and/or one or more dielectric layers, may be formed on the second ILD layer 174 and defined to have patterns of the trenches 178. The second ILD 174 layer, the CESL 176, the first ILD layer 162, and the CESL 160 may then be etched by one or more etch processes according to the patterns of the mask layers. In some embodiments, the epitaxial structures 158 are not significantly etched while forming the trenches 178. In some embodiments, outer portions of the epitaxial structures 158 (e.g., at least a portion of the third semiconductor layer) may also be removed while forming the trenches 178. The one or more etch processes may include a first etch process that substantially stops at the CESL 176, a second etch process to etch through the first ILD layer 162, and a third etch process to remove the CESL 160. In some embodiments, the first etch process, the second etch process, and the third etch process may independently be a dry etch process or a wet etch process with the use of suitable etchants and etching conditions. The CESL 176 may reduce or prevent the first etch process from damaging the gate structure 172. The trenches 178 may not expose the gate structure 172. In some embodiments, depending on the sizes or shapes of the trenches 178, a portion of the gate spacers 134, such as sidewalls of the gate spacers 134, are exposed by the trenches 178, while the top surfaces of the gate electrodes 170 are not exposed by the trenches 178.

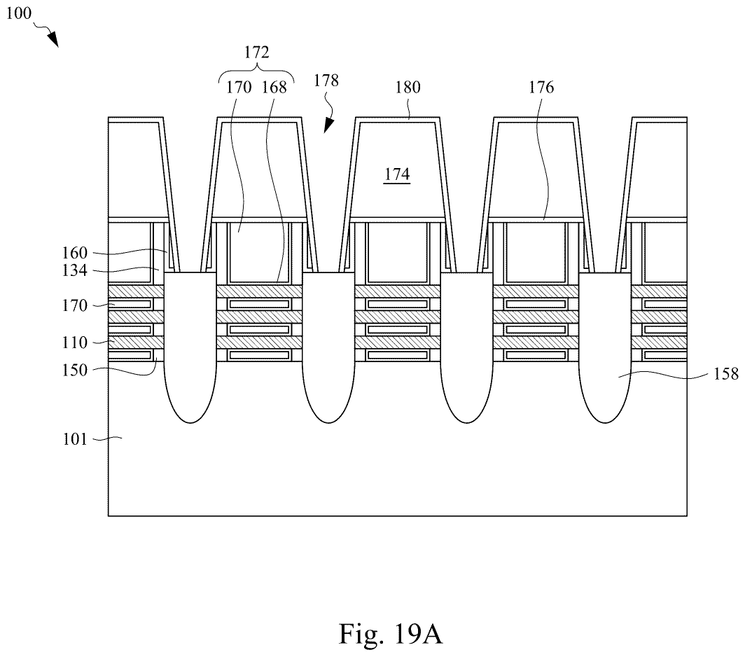

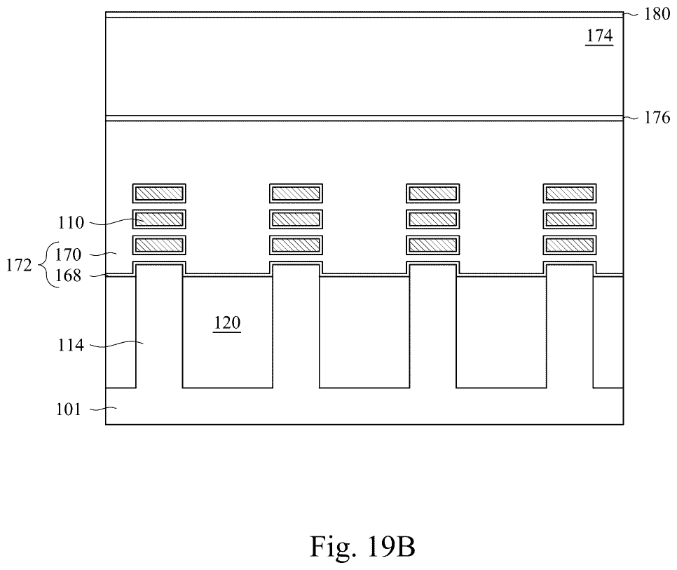

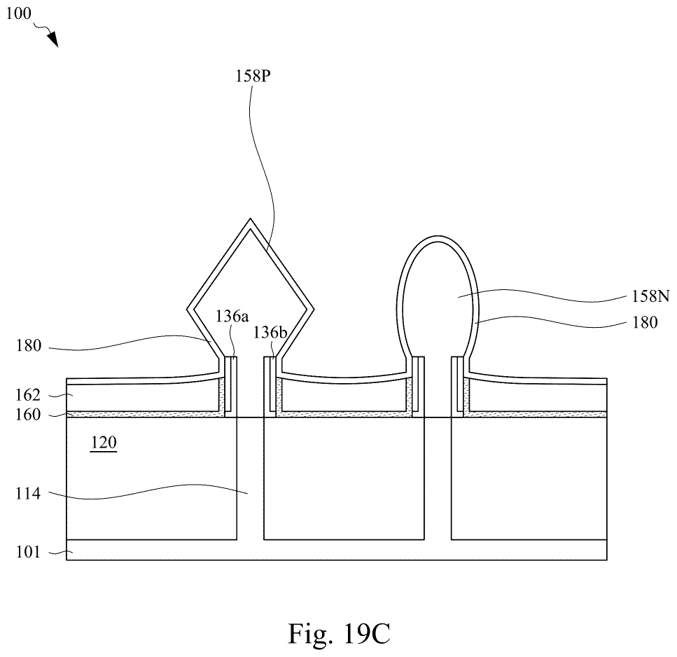

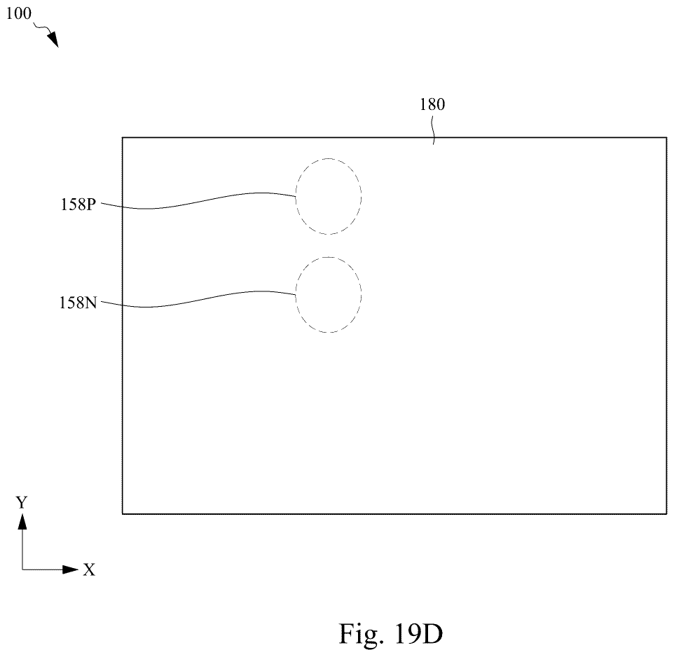

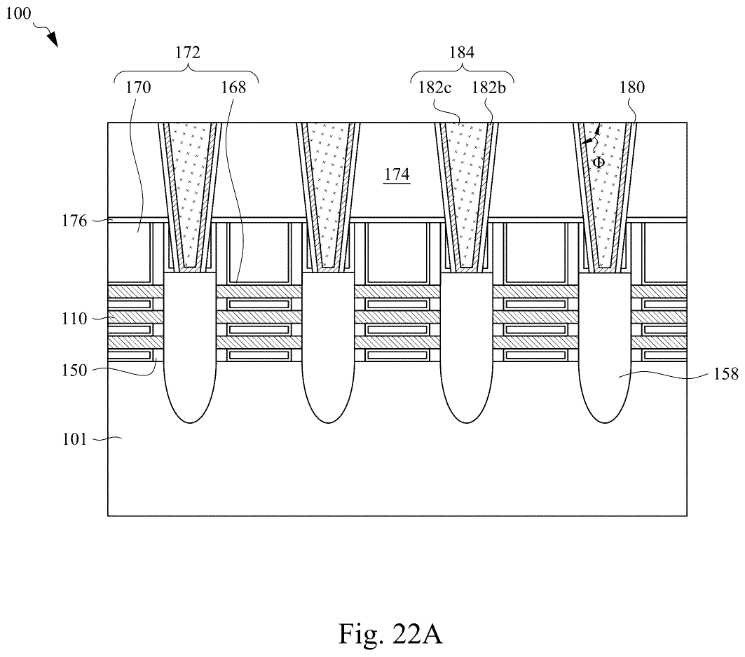

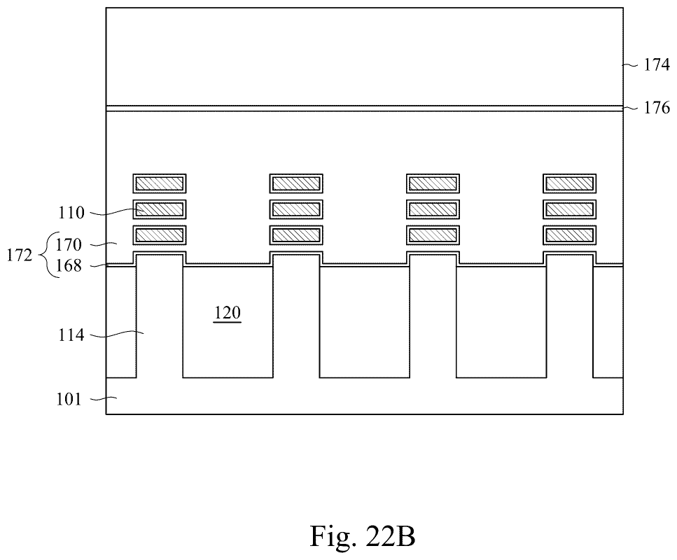

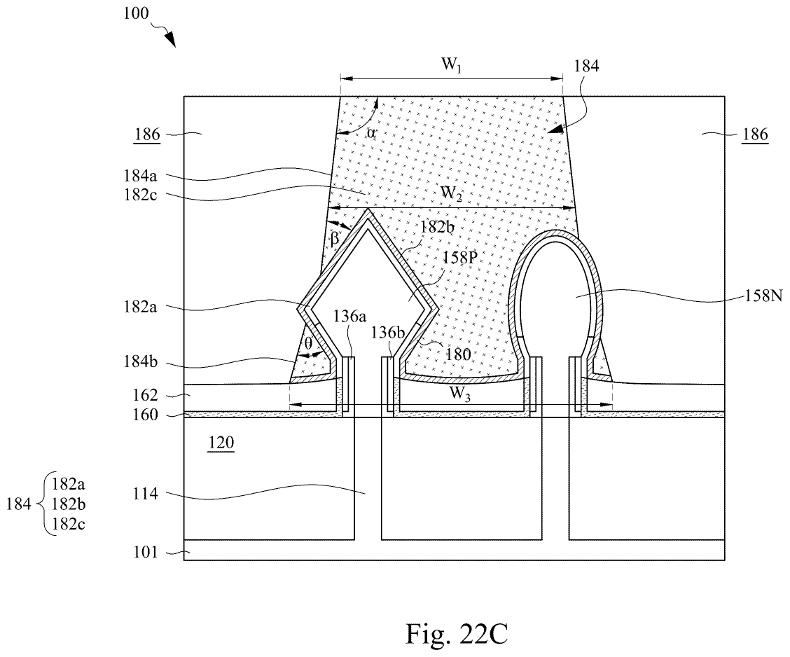

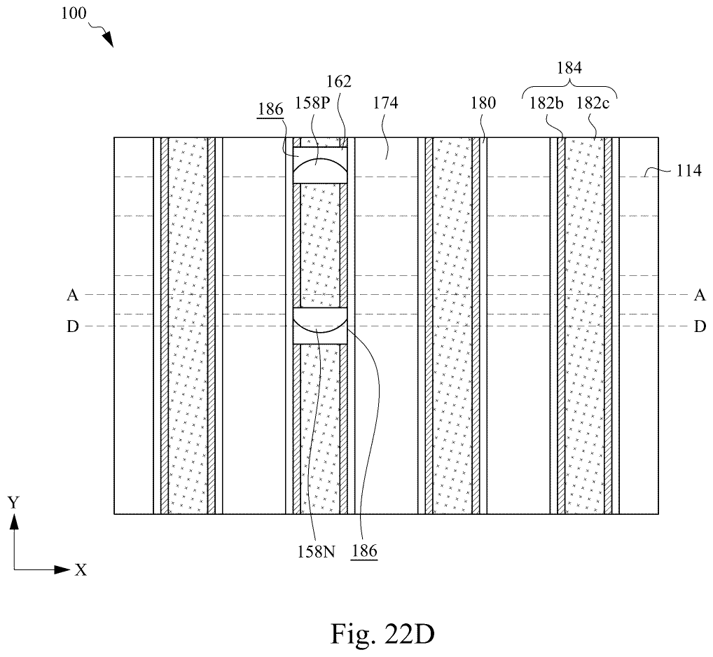

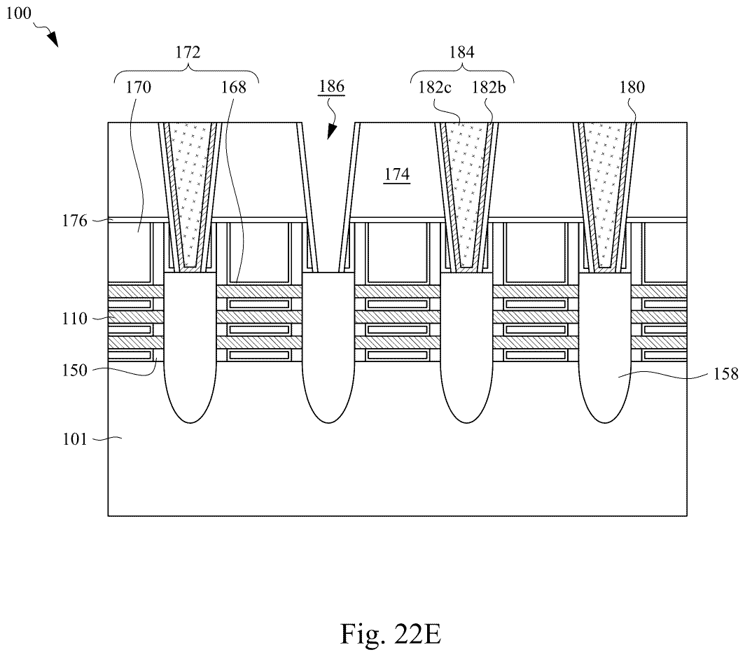

In FIGS. 19A-19D, a dielectric layer 180 is formed in the trenches 178 and cover the exposed portions of the epitaxial structures 158, in accordance with some embodiments. The dielectric layer 180 may be conformally deposited in the trenches 178 and over the top surface of the second ILD layer 174, such as extending on the sidewalls of the trenches 178, on the top surface of the second portions of the first ILD layer 162, and on the exposed surfaces of the epitaxial structures 158. In some embodiments, the dielectric layer 180 is formed of a material having a dielectric constant greater than silicon oxide (e.g., dielectric constant greater than about 3.9), such as SiN, SiON, SiC, SiCN, SiOCN, combinations thereof, or the like. The dielectric layer 180 may have a material different than the material of the CESL 160. For example, in an embodiment, the CESL 160 is a SiN layer, and the dielectric layer 180 is a SiON layer. In some embodiments, the CESL 160 and the dielectric layer 180 include a same base material (e.g., SiON or SiOCN), and the material of dielectric layer 180 includes more oxygen content than the material of the CESL 160. The dielectric layer 180 may have a thickness different from the thickness of the CESL 160, although they can have a same thickness. The dielectric layer 180 may increase the resistance between subsequently formed source/drain contacts 184 (FIG. 22A) and the gate electrodes 170 so that shorts or unwanted leakage between the gate electrodes 170 and the source/drain contacts 184 may be reduced or prevented. The formation of the dielectric layer 180 may be formed by any suitable deposition methods, such as ALD, CVD, PECVD, or other suitable deposition methods.

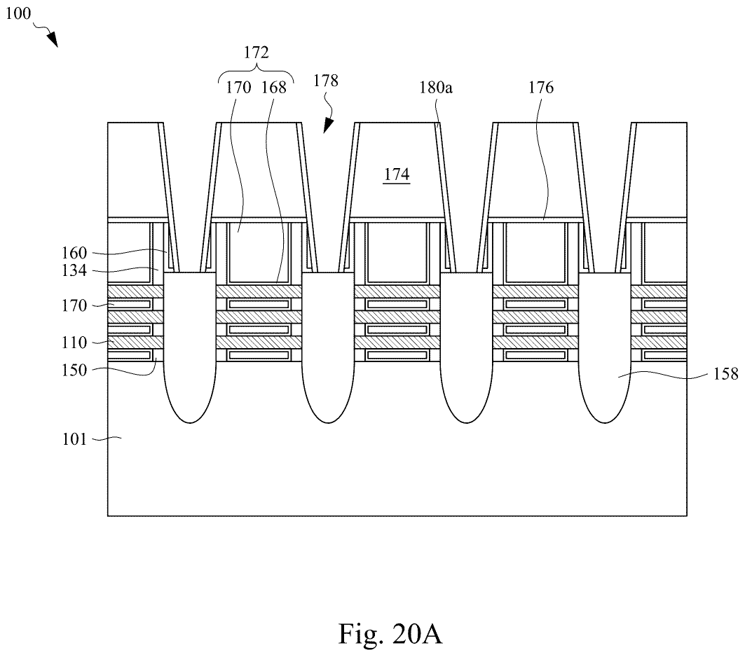

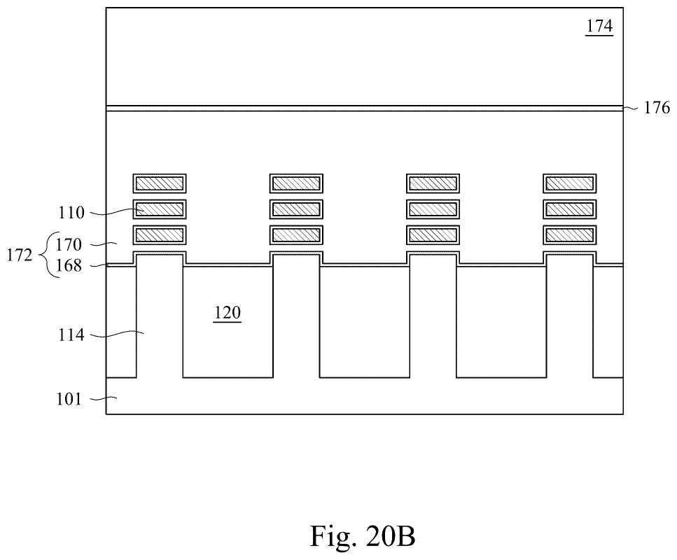

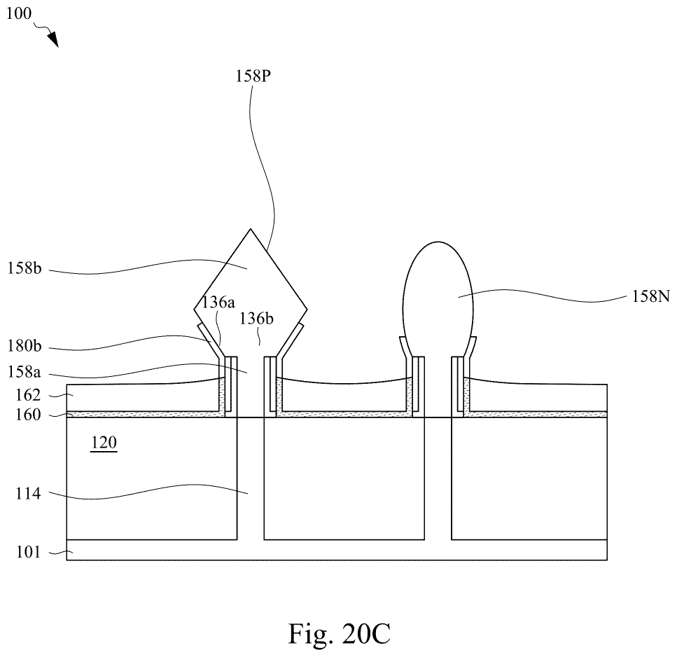

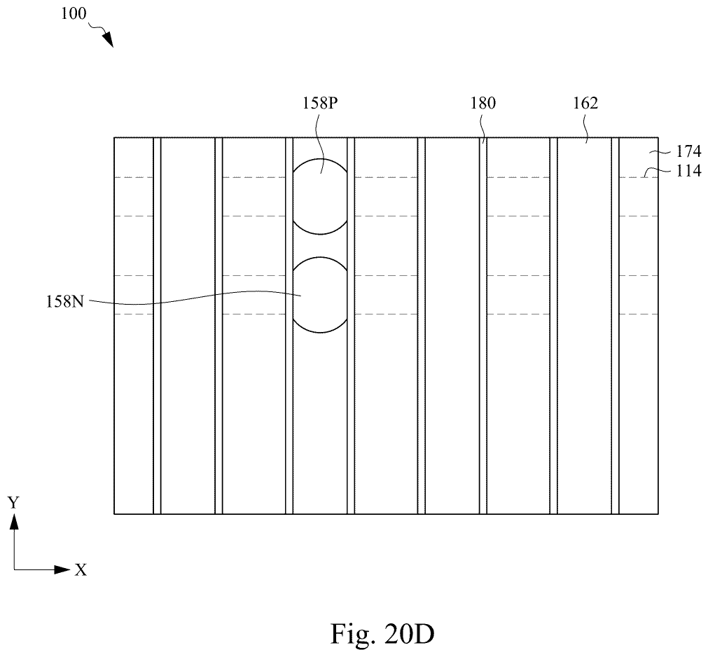

In FIGS. 20A-20D, an etch process is performed to partially remove the dielectric layer 180 to expose the epitaxial structures 158, in accordance with some embodiments. The etch process may include a dry etch that comprises vertically directing etchant to the dielectric layer 180. The dry etch process may include RIE, NBE, or a combination thereof. Accordingly, portions that are on the top surface of the second ILD layer 174, portions of the dielectric layer 180 that are on the epitaxial structures 158, and bottom portions of the dielectric layer 180 that are on the top of the first ILD layer 162 are removed, while leaving sidewall portions 180a of the dielectric layer 180 and a bottom portion 180b of the dielectric layer 180 that is covered by the main structures 158b of the epitaxial structures 158 remained, in accordance with some embodiments. For example, as illustrated in FIG. 20C, bottom portions 180b of the dielectric layer 180 that are on the spacer layers 136 and on the lower portions of the epitaxial structures 158 (e.g., portions of the epitaxial structures 158 below the widest portion in the Y-direction) may remain. The bottom portions 180b of the dielectric layer 180 may have a shape corresponding to the spacer layer 136 and the lower portions of the epitaxial structures 158.

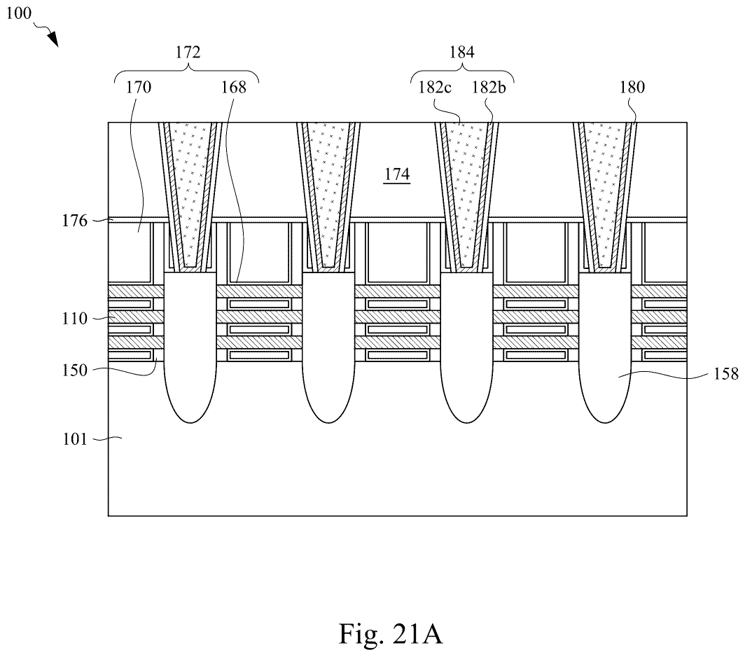

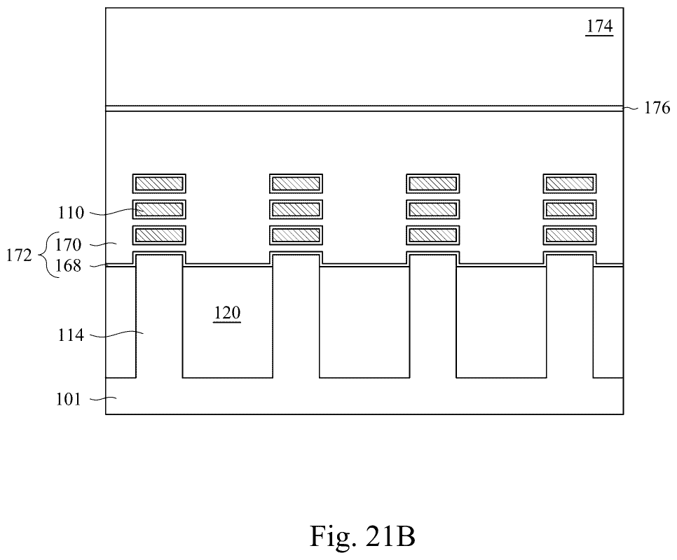

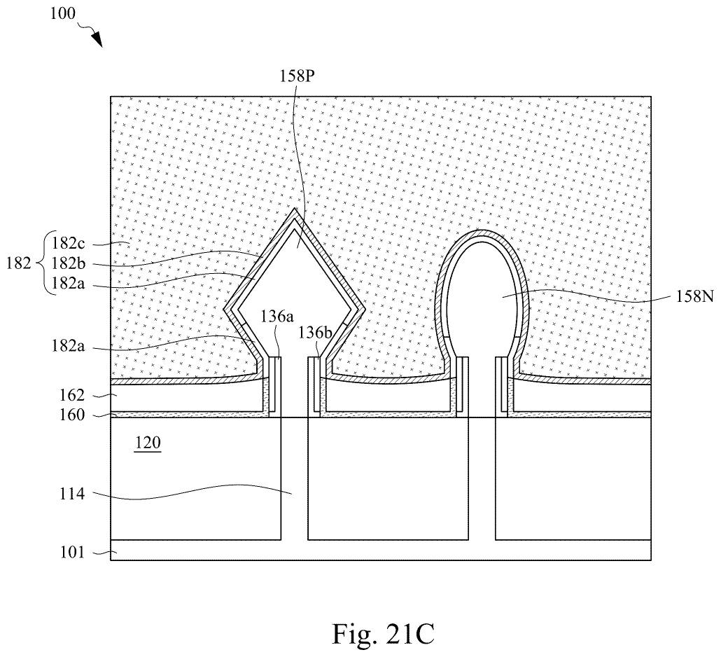

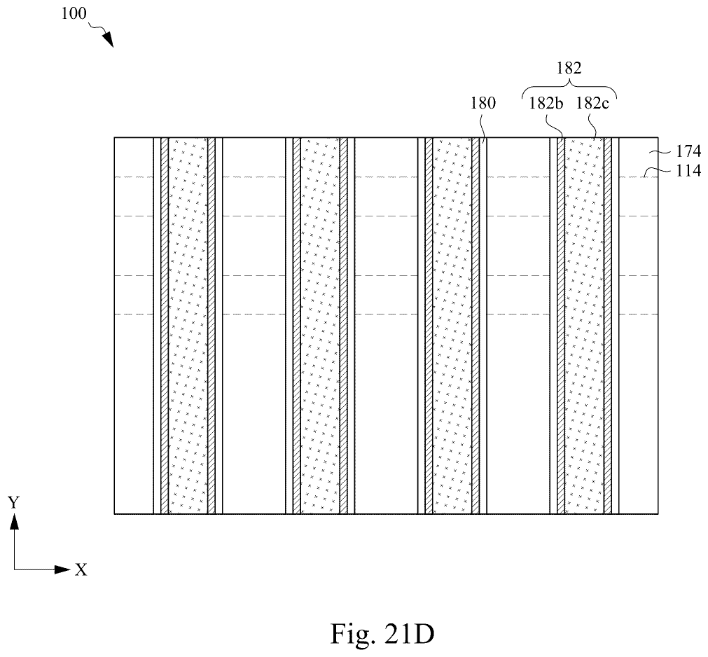

In FIGS. 21A-21D, conductive structures 182 are formed in the trenches 178, in accordance with some embodiments. The conductive structures 182 may have a pattern corresponding to the trenches 178, such as straight lines having longitudinal axis extending along the Y-direction. Each of the conductive structures 182 includes a silicide layer 182a, a conductive liner 182b, and a conductive layer 182c, in accordance with some embodiments. The formation of the silicide layer 182a and the conductive liner 182b may include forming a conformal metal layer in the trenches 178 and over the top surfaces of the second ILD layer 174. The conformal metal layer may cover the exposed surfaces of the epitaxial structures 158, the sidewall portions 180a and the bottom portions 180b of the dielectric layer 180, and the top surface of the first ILD layer 162. In some embodiments that the dielectric layer 180 has a thickness thinner than the thickness of the CESL 160, the conformal metal layer may also be in contact with the CESL 160. The conformal metal layer may be formed by ALD, CVD, PVD, or the like.

An anneal process is then performed to carry out a reaction between the conformal metal layer and the semiconductor materials of the epitaxial structures 158, thereby forming the silicide layer 182a. Because the silicide layer 182a is formed by reacting the conformal metal layer and the epitaxial structures 158, the silicide layer 182a may be self-aligned to the epitaxial structures 158, such as formed on the exposed surfaces of the epitaxial structures 158. In some embodiments, the conformal metal layer may have a sufficient thickness so that the formation of the silicide layer 182a may not completely consume the conformal metal layer. In an embodiment, when the conformal metal layer has a thickness of about 5 nm, about 2.5 nm of the conformal metal layer on the epitaxial structures 158 may be consumed to form the silicide layer 182a. As such, after the forming the silicide layer 182a, the conformal metal layer may have a thickness of about 2.5 nm for portions on the silicide layer 182a and a thickness of about 5 nm for portions that are not on the silicide layer 182a. In some embodiments, the conformal metal layer may include a material of Ti, W, Pt, Ni, or a combination thereof.

In some embodiments, a treatment process is then performed to convert unreacted portions of conformal metal layer to form the conductive liner 182b. The treatment process may include any possible treatment to convert the conformal metal layer to any suitable compound for being a conductive liner 182b. In some embodiments, the treatment process includes a nitridation process to nitridize unreacted portions of the conformal metal layer to metal nitride. In an embodiment that the conformal metal layer is a Ti layer, the conductive liner 182b is a TiN layer. The conductive liner 182b may have a first thickness for portions on the silicide layers 182a and a second thickness for portions that are not on the silicide layers 182b, and second thickness is greater than the first thickness.

In some embodiments, the conductive liner 182b is not formed by the treatment process but by a deposition process. In such embodiments, the conformal metal layer for forming the silicide layer 182a is removed after the silicide layer 182a is formed, and the conductive liner 182b is deposited in the trenches 178 with covering the silicide layer 182a. In the embodiments that the conductive liner 182b is formed by the deposition process, the conductive liner 182b may be a conformal layer having a uniform thickness.

After the conductive liner 182b is formed, a conductive layer 182c is formed. The conductive layer 182c fills the remaining space in the trenches 178, in accordance with some embodiments. The conductive layer 182c may be formed of a metal material that has a lower resistivity than the conductive liner 182b and can be suitably etched. For example, conductive layer 182c may be or include tungsten, cobalt, aluminum, ruthenium, or the like. The conductive layer 182c may be formed by any suitable deposition processes, such as CVD, PVD, plating or other suitable processes. In some embodiments, the conductive liner 182b and the conductive layer 182c include excess portions over the top surfaces of the second ILD layer 174, and a planarization process such as CMP may be performed to remove the excess materials of the conductive liner 182b and the conductive layer 182c over the top surface of the second ILD layer 174. In some embodiments, the conductive liner 182b and the conductive layer 182c also extend into and/or fill in the space between the between the adjacent p-type epitaxial structure 158P and the n-type epitaxial structure 158N illustrated in FIG. 21C.

In FIGS. 22A-22E, an end-cut process is performed on the conductive structures 182 to form source/drain contacts 184, in accordance with some embodiments. FIG. 22E illustrates a cross-sectional view along the D-D section as illustrated in FIG. 22D. The end-cut process includes etching the conductive structures 182 to separate the line-shaped conductive structures 182 to discontinuous segments in the Y-direction. The discontinuous segments may become the source/drain contacts 184.

In some embodiments, the end-cut process includes forming an overlay mask (not shown) over the top surfaces of the conductive structures 182 and the second ILD layer 174. The overlay mask may include one or more photoresist layers over one or more hard mask layers. The overlay mask may be defined as having metal cut regions. The metal cut regions may have a length along the X-direction and a width along the Y-direction, and a ratio of the length to width is about 0:5:1 to 1:0.5. An etch process may be performed to etch the conductive structure 182 through the metal cut regions of the overlay mask, thereby forming openings 186. For example, the conductive layer 182c and the conductive liner 182b under the metal cut regions may be removed for forming the openings 186. The openings 186 extend through the conductive structures 182 to separate the conductive structures 182 to the source/drain contacts 184. In some embodiments, the openings 186 partially expose the epitaxial structures 158. The conductive liner 182b may protect the underlying silicide layer 182 and the epitaxial structures 158 during the formation of the openings 186. The overlay mask may be removed after the openings 186 and the source/drain contacts 184 are formed.

The etch process may include a wet etch, a dry etch, and/or a combination thereof. As an example, a dry etching process may implement fluorine-containing gas (e.g., CF₄, SF₆, CH₂F₂, CHF₃, and/or C₂F₆), chlorine-containing gas (e.g., Cl₂, CHCl₃, CCl₄, and/or BCl₃), bromine-containing gas (e.g., HBr and/or CHBr₃), iodine-containing gas, other suitable gases and/or plasmas, and/or combinations thereof. Due to the etching behavior, the openings 186 may be gradually narrowed toward the bottom, thereby having a wide top width and a narrow bottom width. Accordingly, as illustrated in FIG. 22C, the source/drain contact 184 may have a first width W₁ at the top of the source/drain contact 184, a second width W₂ at a level of near the top of the epitaxial structure 158 (e.g., p-type epitaxial structure 158P), and a third width W₃ at a bottom of the source/drain contact 184, in accordance with some embodiments. The third width W₃ is greater than the second width W₂, and the second width W₂ is greater than the first width W₁.

In some embodiments, the source/drain contact 184 has a first sidewall 184a at least extend from the top surface of the source/drain contact 184 to an upper portion of the epitaxial structure 158, a second sidewall 184b extend from a lower portion of the epitaxial structure 158 to a top surface of the first ILD layer 162. The first sidewall 184a and the second sidewall 184b of the source/drain contact 184 may have different slope with the z-axis as illustrated in FIG. 6. In some embodiments, a first angle α between the first sidewall 184a of the source/drain contact 184 and the top surface of the source/drain contact 184 is greater than 90 degrees, such as in a range from about 95 degrees to about 170 degrees, or in a range from about 100 degrees to about 135 degrees. A second angle β between the first sidewall 184a of the source/drain contact 184 and an upper surface of the source/drain contact 184 is less than 90 degrees, such as in a range from about 10 degrees to about 80 degrees. A third angle θ between the first sidewall 184a of the source/drain contact 184 and a lower surface of the source/drain contact 184 is less than 90 degrees, such as in a range from about 10 degrees to about 80 degrees. In an embodiment as illustrated in FIG. 22C, first sidewall 184a and the second sidewall 184b may have a vertical gap in a range from about 1 nm to about 10 nm. As illustrated in FIG. 22A, the source/drain contact 184 has a fourth angle Φ between a sidewall and a top surface, and the fourth angle Φ is less than 90 degrees, such as in a range from about 50 degrees to about 85 degrees.

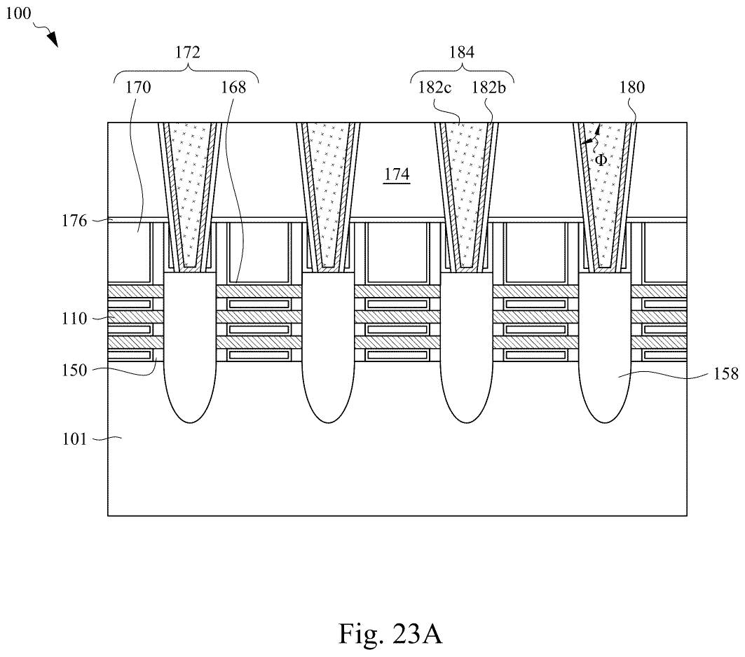

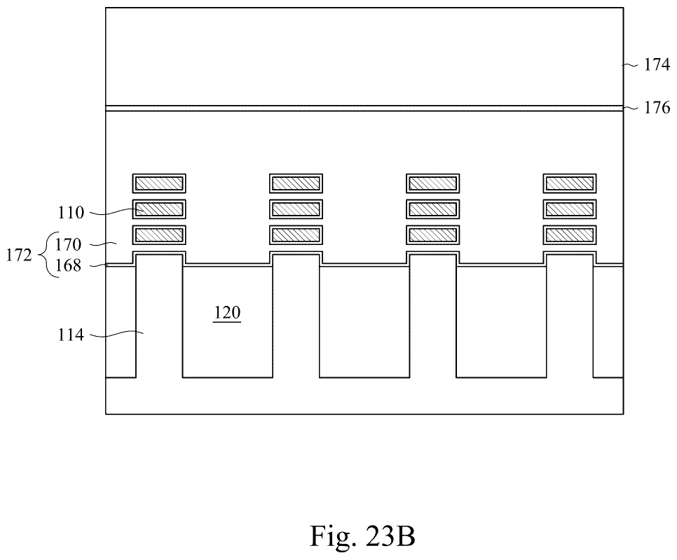

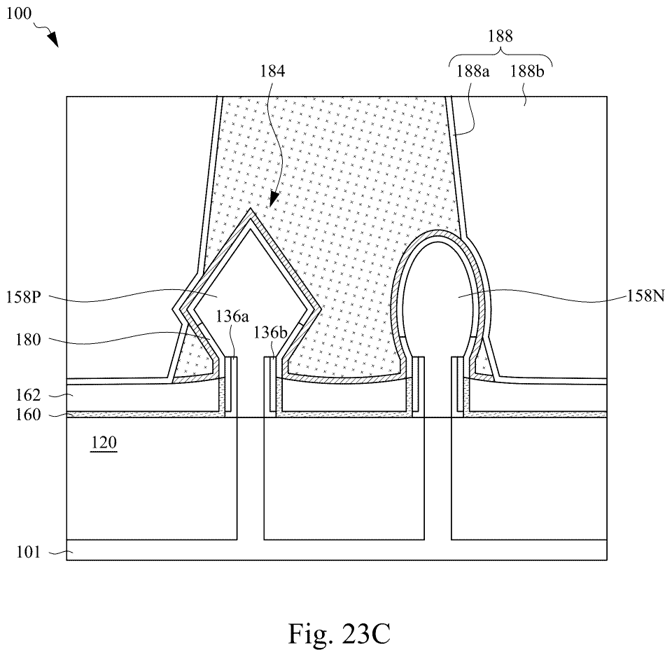

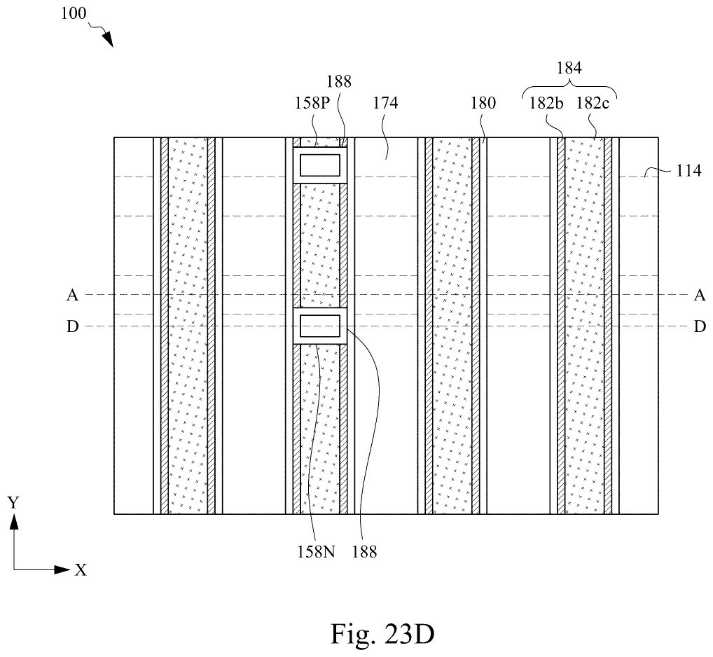

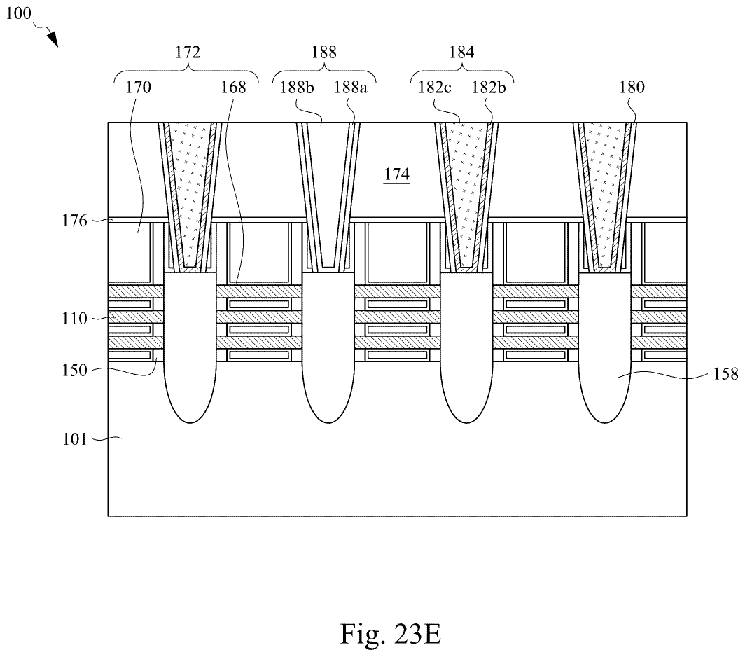

In FIGS. 23A-23E isolation regions 188 are formed in the openings 186, in accordance with some embodiments. FIG. 23E illustrates a cross-sectional view along the D-D section as illustrated in FIG. 23D. The isolation regions 188 may each include a dielectric liner 188a and a dielectric filling 188b over the dielectric liner 188a. The dielectric liner 188a may be a conformal layer. The dielectric liner 188a may be formed by ALD, CVD, PECVD, or the like. In some embodiments, the dielectric liner 188a is formed of a material different from the dielectric layer 180 and the CESL 160, although the dielectric liner 188a may be formed of a material similar to those of the dielectric layer 180 or the CESL 160. For example, the dielectric liner 188a may include SiN, SiON, SiC, SiCN, SiOCN, combinations thereof, or the like. The dielectric liner 188a may provide good adhesiveness between source/drain contacts 184 and the dielectric filling 188b and/or can act as a protection layer for the second ILD layer 174 when performing a planarization process. In some embodiments, the dielectric liner 188a has a thickness different from the thickness of the dielectric layer 180 or the CESL 160. In some embodiments, dielectric liner 188a can be omitted.

The dielectric filling 188b may be formed over the dielectric liner 188a and fill in the remaining space of the openings 186. The dielectric filling 188b may be formed of a material similar to those of the first ILD layer 162 and/or the second ILD layer 174 and formed by processes similar to those used for the first ILD layer 162 and/or the second ILD layer 174 For example, the dielectric filling 188b may include a material made of silicon oxide, silicon nitride, silicon oxynitride, SiOCN, SiCN, fluorine-doped silicate glass (FSG), a low-K dielectric material (dielectric constant less than about 3.5), or any suitable dielectric material. A planarization process may be performed to remove the dielectric liner 188a and the dielectric filling 188b over the top surfaces of the second ILD layer 174. After the planarization process, top surfaces of the dielectric liner 188a, the dielectric filling 188b, the source/drain contacts 184, and the second ILD layer 174 may be level with each other.

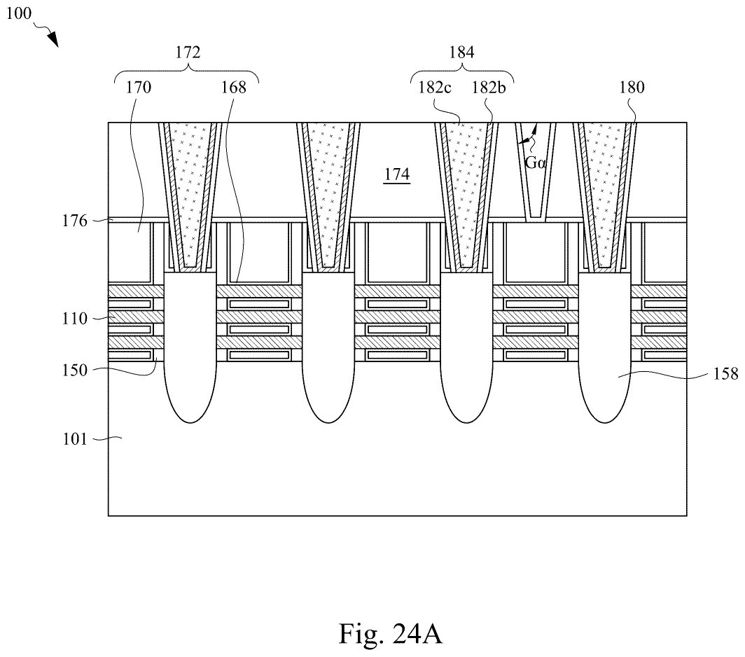

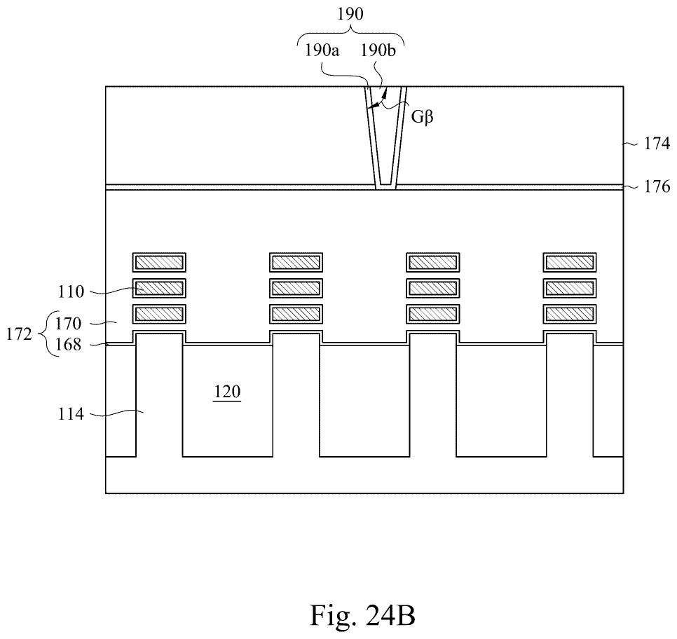

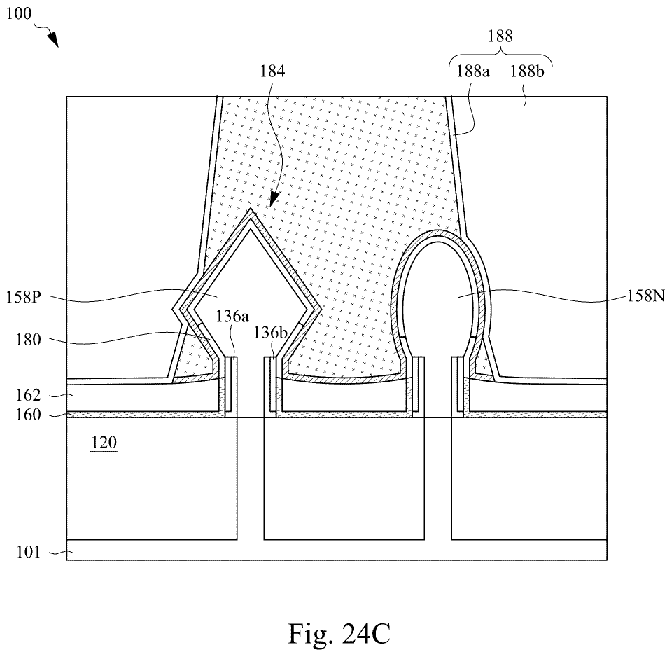

In FIGS. 24A-24C, gate contacts 190 are formed in the second ILD layer 174, in accordance with some embodiments. In some embodiments, the gate contacts 190 are formed by forming openings in the second ILD layer 174 and the CESL 176 and then depositing a conductive material into the openings. In some embodiments, the openings for the gate contact 190 may be formed by one or more etch processes. The etch processes may be dry etch or wet etch. In an embodiment, RIE, NBE or other suitable etch processes are used for forming the openings for gate contacts 190. The openings for gate contacts 190 may extend from atop surface of the second ILD layer 174 and through the second ILD layer 174 and the CESL 176 to expose the gate electrodes 170. After the openings for gate contacts 190 are formed, a conductive liner 190a and a conductive layer 190b may be formed in the openings subsequently. The conductive liner 190a may be a conformal layer. For example, the conductive liner 190a may be formed by ALD, CVD, PVD, or the like. In some embodiments, the conductive liner 190a includes a metal nitride, such as TaN, TiN or WN, a combination thereof, or the like. The conductive layer 190b may fill in the remaining space of the openings. For example, the conductive layer 190b may be formed by CVD, PVD, plating, or the like. The conductive layer 190b may include tungsten, cobalt, aluminum, ruthenium, copper, or the like. The conductive layer 190b of the gate contact 190 and the conductive layer 182c of the source/drain contact 184 may be formed of different materials.

In some embodiments, the as-deposited conductive liner 190a and the as-deposited conductive layer 190b also extend over the top surface of second ILD layer 174. A planarization process such as CMP may be performed to remove excess portions of the conductive liner 190a and the conductive layer 190b over the top surface of the second ILD layer 174. The conductive liner 190a may improve the adhesive between second ILD layer 174 and conductive layer 190b and reduce diffusion of the conductive layer 190b into the second ILD layer 174. However, the conductive liner 190a can be omitted in some embodiments.

Referring to FIG. 24A, an angle Gα between a sidewall of the gate contact 190 and a top surface of the gate contact 190 in the X-direction is less than 90 degrees, such as in a range from about 30 degrees to about 85 degrees. Also referring to FIG. 24B, an angle Gβ between a sidewall of gate contact 190 and a top surface of the gate contact 190 in the Y-direction is also less than 90 degrees, such as in a range from about 30 degrees to about 85 degrees.

Embodiments of present disclosure provide a method for mitigating the risks of shorts or leakage between two source/drain contacts 184 in the Y-direction or between a source/drain contact 184 and the gate structure 172 in the X-direction. For example, the processes for forming the source/drain contacts 184 may include forming metal line forming steps (e.g., conductive structures 182) and a metal end-cut step, wherein the metal end-cut step may separate the metal lines to source/drain contacts 184. The end-cut processes may provide precise dimension control for the spacing between two contacts. Thus, the line-forming/end-cut method as described above may provide better critical dimension control for the space between two adjacent source/drain contacts 184 in the Y-direction and the spacing between a source/drain contact 184 and the gate structure 172 in the X-direction, as compared to methods that directly creating boundaries of the source/drain contacts by directly transferring patterns of the source/drain contacts from masks (e.g., methods similar to form the gate contacts 190). Accordingly, the risks of shorts between two source/drain contacts 184 in the Y-direction or between a source/drain contact 184 and the gate structure 172 in the X-direction may be thus mitigated using the line-forming/end-cut methods provided by embodiments of the present disclosure.

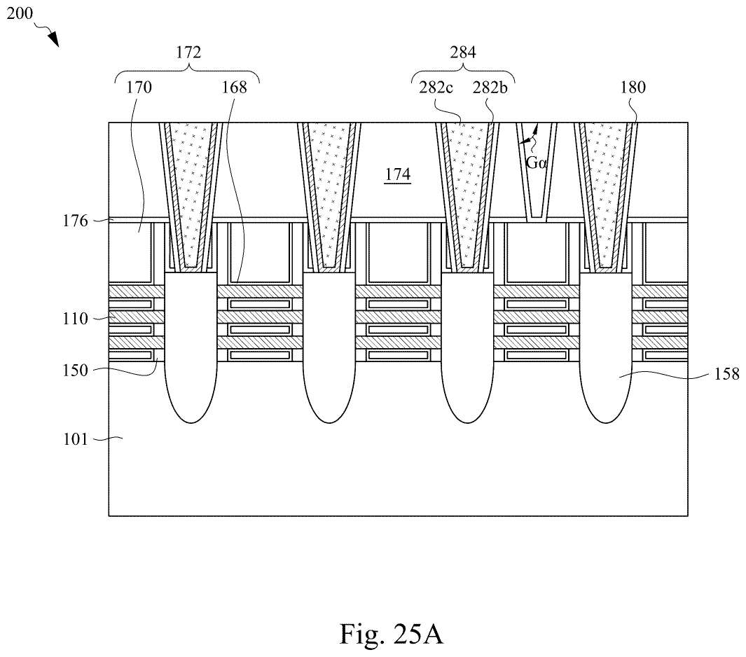

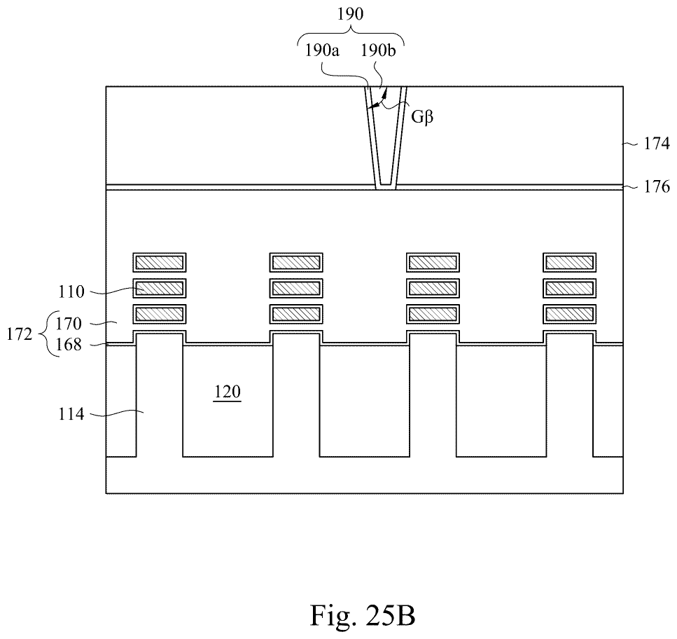

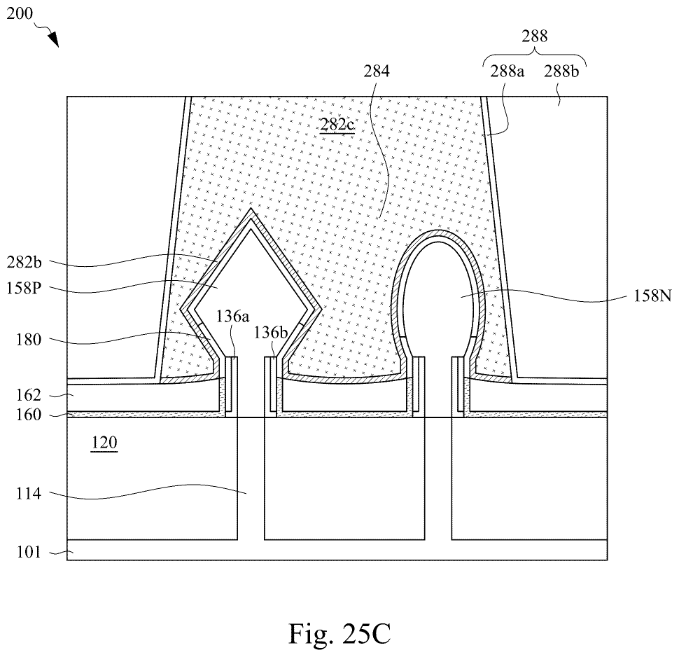

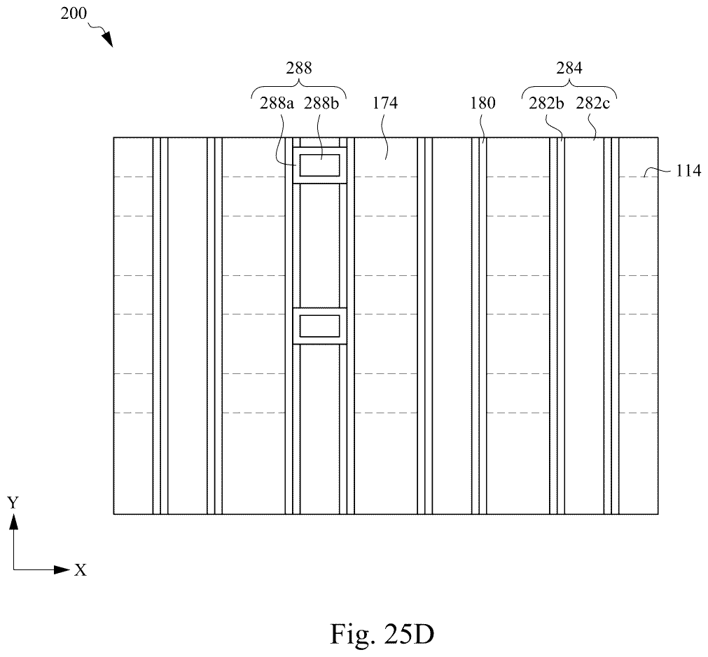

FIGS. 25A-25D illustrate cross-sectional views and a plan view of an intermediate stage of a semiconductor device 200, in accordance with some embodiments. FIGS. 25A-25C may correspond to FIGS. 24A-24C, and the isolation regions 288 are not in contact with epitaxial structures 158. FIG. 25D is a plan view of the intermediate stage of the semiconductor device 200. The epitaxial structures 158 may not be damaged in the metal end-cut processes. The isolation regions 288 may include materials similar to those of the isolation regions 188, such as including a filling dielectric 288b similar to the dielectric filling 188b and an optional dielectric liner 188a similar to the dielectric liner 188a. The isolation regions 288 may be formed by methods similar to those used for forming the isolation regions 188. As illustrated in FIG. 25C, the sidewalls of the source/drain contacts 284 may continuously extend from a top surface of source/drain contact 184 to a bottom surface of the source/drain contact 184. The source/drain contacts 284 may be similar to the source/drain contacts 184. In such embodiments, the low-resistivity conductive layer 282b can have an increased volume, and the resistivity of the source/drain contacts 284 can be correspondingly reduced. In an embodiment, the isolation regions 188 may overlap the epitaxial structure 158 in the plan view. In some embodiments, the isolation regions 188 do not overlap the epitaxial structure 158 in the plan view.

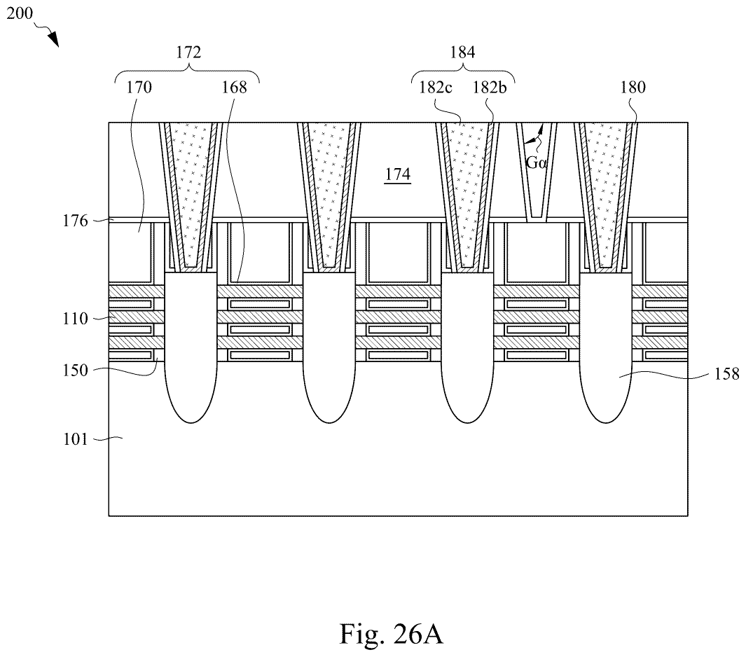

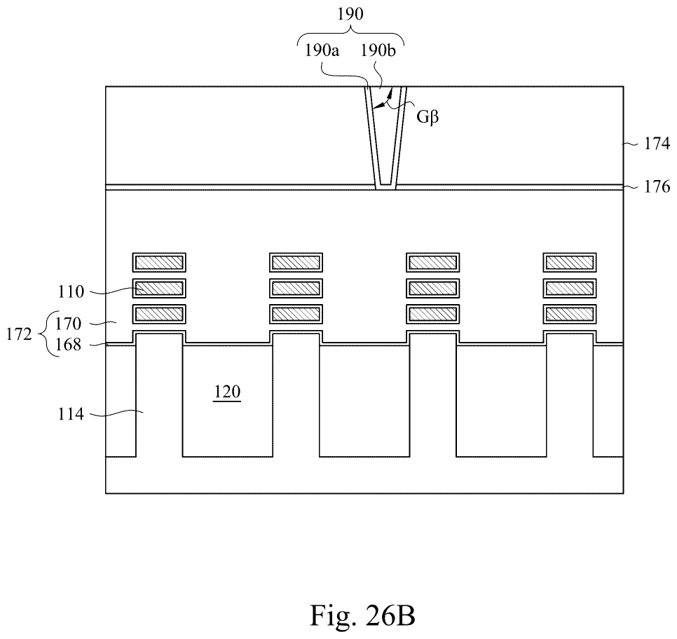

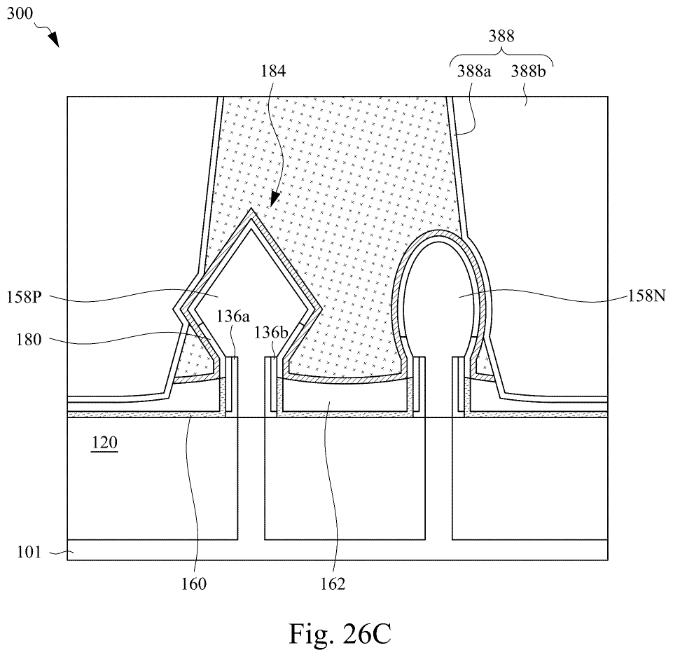

FIGS. 26A-26C illustrate cross-sectional views and a plan view of an intermediate stage of a semiconductor device 300, in accordance with some embodiments. FIGS. 26A-26C may correspond FIGS. 24A-24C, and the isolation regions 388 may have a bottom lower than a bottom of the source/drain contact 184. In some embodiments, the openings 186 (FIG. 22C) are over-etched, such as recessed into the first ILD layer 162, to make sure residues of the conductive structures 182 in the openings 186 be completely removed. The isolation regions 388 may include materials similar to those of the isolation regions 188, such as a filling dielectric 388b similar to the dielectric filling 188b and an optional dielectric liner 388a similar to the dielectric liner 188a.

Embodiments of the present disclosure provide methods for forming source/drain contacts and structures manufactured thereof. In some embodiments, the methods for forming the source/drain contacts may include forming metal lines and cutting the metal lines by an end-cut process to separate the metal lines to the source/drain contacts. The end-cut process may provide precise critical dimension control and thus can help mitigate the risks of forming shorts between adjacent source/drain contacts and/or between a gate structure and its adjacent source/drain contact.

An embodiment is a semiconductor device that includes a channel region connecting to an epitaxial structure in a first direction; a gate structure disposed over the channel region and having a longitudinal axis extending in a second direction substantially perpendicular to the first direction; and a contact disposed over the epitaxial structure, the contact including a sidewall in the second direction, wherein a first angle between the sidewall and a top surface of the contact is greater than 90 degrees. In an embodiment, the semiconductor device further includes a first dielectric layer over the gate structure, wherein the contact extends through the first dielectric layer, wherein the top surface of the contact is level with a top surface of the first dielectric layer. In an embodiment, the semiconductor device further includes a first isolation region and a second isolation region disposed on opposite sides of the contact in the second direction. In an embodiment, a top surface of the first isolation region is level with the top surface of the first dielectric layer. In an embodiment, the contact includes a conductive liner and a conductive layer over the conductive liner, wherein the conductive layer is in physical contact with the first isolation region and the second isolation region. In an embodiment, the semiconductor device further includes a second dielectric layer formed of a material having a dielectric constant greater than 3.9, wherein the second dielectric layer includes a first portion disposed between the contact and the gate structure. In an embodiment, the second dielectric layer further includes a second portion in physical contact with the epitaxial structure and separated from the first portion of the second dielectric layer.

Another embodiment is a semiconductor device that includes a first gate structure and a second gate structure disposed laterally adjacent to a first dielectric layer; a second dielectric layer disposed over the first gate structure, the second gate structure, and the first dielectric layer; a first epitaxial structure disposed between the first gate structure and the second gate structure in a first direction; a contact electrically coupled to the first epitaxial structure, wherein the contact has a top surface level with a top surface of the second dielectric layer; and a first isolation region and a second isolation region interposing the contact in a second direction perpendicular to the first direction, wherein a first angle between a first sidewall of the contact and the top surface of the contact in the second direction is greater than 90 degrees. In an embodiment, the first isolation region and the second isolation region each has a top surface level with the top surface of the second dielectric layer and each has a bottom surface lower than a bottom surface of the second dielectric layer. In an embodiment, the contact includes a conductive liner and a conductive layer over the conductive liner, wherein the conductive layer is in physical contact with the first isolation region and the second isolation region. In an embodiment, the conductive layer is separated from the first epitaxial structure and the first dielectric layer by the conductive liner. In an embodiment, a second angle between a second sidewall of the contact and the top surface of the contact in the first direction is less than 90 degrees. In an embodiment, the semiconductor device further includes a second epitaxial structure disposed between the first gate structure and the second gate structure, wherein the contact extends between the first epitaxial structure and the second epitaxial structure and is in physical contact with the second epitaxial structure. In an embodiment, the semiconductor device further includes a third dielectric layer including a first portion disposed between the contact and the first gate structure and a second portion disposed between the contact and the second gate structure, wherein each of the first portion and the second portion of the third dielectric layer has a top surface level with the top surface of the contact and has a longitudinal axis extending in the second direction.

A further embodiment is a method for forming a semiconductor device, the method including: forming an epitaxial structure connecting to a channel region in a first direction; forming a gate structure over the channel region, wherein the gate structure has a longitudinal axis extending in a second direction substantially perpendicular to the first direction; and forming a contact over the epitaxial structure, the contact including a first sidewall in the second direction, wherein a first angle between the first sidewall and a top surface of the contact is greater than 90 degrees. In an embodiment, forming the contact includes forming a first dielectric layer covering the epitaxial structure; forming the gate structure in first dielectric layer; forming a second dielectric layer over the gate structure and the first dielectric layer; forming a first opening in the second dielectric layer and the first dielectric layer to expose the epitaxial structure, wherein the first opening has a longitudinal axis in the second direction; forming a conductive structure in the first opening; etching the conductive structure to form a second opening and a third opening, wherein the second opening and the third opening cut the conductive structure to the contact; and forming a first isolation region and a second isolation region in the second opening and the third opening, respectively. In an embodiment, the second opening and the third opening each has a bottom surface below a bottom surface of the second dielectric layer. In an embodiment, a length of the second opening in the second direction is smaller than a length of the first opening in the second direction. In an embodiment, the method further includes forming a third dielectric layer in the first opening, wherein forming third dielectric layer includes depositing a conformal layer in the first opening and partially removing a bottom portion of the conformal layer. In an embodiment, the contact has a second sidewall in the first direction, wherein a second angle between the second sidewall and the top surface of the contact is less than 90 degrees.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a channel region connecting to an epitaxial structure in a first direction;
a gate structure disposed over the channel region and having a longitudinal axis extending in a second direction substantially perpendicular to the first direction; and
a contact disposed over the epitaxial structure, the contact comprising a sidewall in the second direction, wherein a first angle between the sidewall and a top surface of the contact is greater than 90 degrees.

2. The semiconductor device of claim 1, further comprising a first dielectric layer over the gate structure, wherein the contact extends through the first dielectric layer, wherein the top surface of the contact is level with a top surface of the first dielectric layer.

3. The semiconductor device of claim 2, further comprising a first isolation region and a second isolation region disposed on opposite sides of the contact in the second direction.

4. The semiconductor device of claim 3, wherein a top surface of the first isolation region is level with the top surface of the first dielectric layer.

5. The semiconductor device of claim 4, wherein the contact comprises a conductive liner and a conductive layer over the conductive liner, wherein the conductive layer is in physical contact with the first isolation region and the second isolation region.

6. The semiconductor device of claim 1, further comprising a second dielectric layer formed of a material having a dielectric constant greater than 3.9, wherein the second dielectric layer comprises a first portion disposed between the contact and the gate structure.

7. The semiconductor device of claim 6, wherein the second dielectric layer further comprises a second portion in physical contact with the epitaxial structure and separated from the first portion of the second dielectric layer.

8. A semiconductor device, comprising:
a first gate structure and a second gate structure disposed laterally adjacent to a first dielectric layer;
a second dielectric layer disposed over the first gate structure, the second gate structure, and the first dielectric layer;
a first epitaxial structure disposed between the first gate structure and the second gate structure in a first direction;
a contact electrically coupled to the first epitaxial structure, wherein the contact has a top surface level with a top surface of the second dielectric layer; and
a first isolation region and a second isolation region interposing the contact in a second direction perpendicular to the first direction, wherein a first angle between a first sidewall of the contact and the top surface of the contact in the second direction is greater than 90 degrees.

9. The semiconductor device of claim 8, wherein the first isolation region and the second isolation region each has a top surface level with the top surface of the second dielectric layer and each has a bottom surface lower than a bottom surface of the second dielectric layer.

10. The semiconductor device of claim 8, wherein the contact comprises a conductive liner and a conductive layer over the conductive liner, wherein the conductive layer is in physical contact with the first isolation region and the second isolation region.

11. The semiconductor device of claim 10, wherein the conductive layer is separated from the first epitaxial structure and the first dielectric layer by the conductive liner.

12. The semiconductor device of claim 8, wherein a second angle between a second sidewall of the contact and the top surface of the contact in the first direction is less than 90 degrees.

13. The semiconductor device of claim 8, further comprising a second epitaxial structure disposed between the first gate structure and the second gate structure, wherein the contact extends between the first epitaxial structure and the second epitaxial structure and is in physical contact with the second epitaxial structure.

14. The semiconductor device of claim 8, further comprising a third dielectric layer comprising a first portion disposed between the contact and the first gate structure and a second portion disposed between the contact and the second gate structure, wherein each of the first portion and the second portion of the third dielectric layer has a top surface level with the top surface of the contact and has a longitudinal axis extending in the second direction.

15. A method of forming a semiconductor device, the method comprising:
forming an epitaxial structure connecting to a channel region in a first direction;
forming a gate structure over the channel region, wherein the gate structure has a longitudinal axis extending in a second direction substantially perpendicular to the first direction; and
forming a contact over the epitaxial structure, the contact comprising a first sidewall in the second direction, wherein a first angle between the first sidewall and a top surface of the contact is greater than 90 degrees.

16. The method of claim 15, wherein forming the contact comprises:
forming a first dielectric layer covering the epitaxial structure;
forming the gate structure in the first dielectric layer;
forming a second dielectric layer over the gate structure and the first dielectric layer;
forming a first opening in the second dielectric layer and the first dielectric layer to expose the epitaxial structure, wherein the first opening has a longitudinal axis in the second direction;
forming a conductive structure in the first opening;
etching the conductive structure to form a second opening and a third opening, wherein the second opening and the third opening cut the conductive structure to the contact; and
forming a first isolation region and a second isolation region in the second opening and the third opening, respectively.

17. The method of claim 16, wherein the second opening and the third opening each has a bottom surface below a bottom surface of the second dielectric layer.

18. The method of claim 16, wherein a length of the second opening in the second direction is smaller than a length of the first opening in the second direction.

19. The method of claim 18, further comprising forming a third dielectric layer in the first opening, wherein forming third dielectric layer comprises depositing a conformal layer in the first opening and partially removing a bottom portion of the conformal layer.

20. The method of claim 15, wherein the contact has a second sidewall in the first direction, wherein a second angle between the second sidewall and the top surface of the contact is less than 90 degrees.
